(19) United States
(12) Patent Application Publication
(10) Pub. No.: US 2024/0276733 A1
(43) Pub. Date: Aug. 15, 2024

(54) SEMICONDUCTOR MEMORY DEVICE

(71) Applicant: Samsung Electronics Co., Ltd., Suwon-si (KR)

(72) Inventors: Hyuncheol KIM, Suwon-si (KR); Yongseok KIM, Suwon-si (KR); Sanghyun PARK, Suwon-si (KR); Kiheun LEE, Suwon-si (KR); Sangwoo HAN, Suwon-si (KR)

(73) Assignee: Samsung Electronics Co., Ltd., Suwon-si (KR)

(21) Appl. No.: 18/405,361

(22) Filed: Jan. 5, 2024

(30) Foreign Application Priority Data
Feb. 15, 2023 (KR) 10-2023-0020375

(51) Int. Cl. H10B 51/30; H10B 51/20

(52) U.S. Cl. CPC H10B 51/30; H10B 51/20

(57) ABSTRACT

A semiconductor memory device includes a substrate, a semiconductor pattern on the substrate and including a source region having a first conductivity type, a drain region having a second conductivity type, and an intrinsic region between the source region and the drain region, first and second gate electrodes on the intrinsic region, a ferroelectric pattern between the intrinsic region and the first and second gate electrodes, and a gate dielectric pattern between the ferroelectric pattern and the intrinsic region.

### CROSS-REFERENCE TO RELATED APPLICATION

This U.S. nonprovisional application claims priority under 35 U.S.C § 119 to Korean Patent Application No. 10-2023-0020375 filed on Feb. 15, 2023 in the Korean Intellectual Property Office, the disclosure of which is hereby incorporated by reference in its entirety.

### BACKGROUND

Various example embodiments relate to a semiconductor memory device, and more particularly, to semiconductor memory device capable of operating in volatile and non-volatile memory modes.

Semiconductor memory devices include a non-volatile memory device such as Flash memory such as NAND Flash memory and/or NOR Flash memory, and a volatile memory device such as DRAM and/or SRAM.

The non-volatile memory device can maintain data stored in a memory cell even when power supply is interrupted, but consumes much time to write or erase data. The non-volatile memory device may be limited in terms of the number of cycles of writing or erasing data. The volatile memory device cannot maintain data stored in a memory cell when power supply is turned off. However, as the volatile memory device requires a short time to rewrite data, there is no or less limitations in the number of cycles of rewriting data. Thus, there has been suggested a semiconductor memory device having both of non-volatile memory properties and volatile memory properties.

In addition, an electronic system requiring data storage needs or uses a semiconductor device capable of storing high-capacity data, and thus studies have been conducted to increase data storage capacity of the semiconductor device. For example, as an approach to increase data storage capacity of the semiconductor device, a semiconductor device has been suggested to include three-dimensionally arranged memory cells instead of two-dimensionally arranged memory cells.

### SUMMARY

Some example embodiments provide a semiconductor memory device capable of operating in volatile and non-volatile memory modes, and/or of having increased integration.

Example features are not limited to the mentioned above, and other objects which have not been mentioned above will be clearly understood to those of ordinary skill in the art in the art from the following description.

According to some example embodiments, a semiconductor memory device may include a substrate; a semiconductor pattern on the substrate, wherein the semiconductor pattern includes a source region having a first conductivity type, a drain region having a second conductivity type, and an intrinsic region between the source region and the drain region; first and second gate electrodes on the intrinsic region; a ferroelectric pattern between the intrinsic region and the first and second gate electrodes; and a gate dielectric pattern between the ferroelectric pattern and the intrinsic region.

Alternatively or additionally according to some example embodiments, a semiconductor memory device may include a substrate; a plurality of semiconductor patterns that are stacked along a first direction that is perpendicular to a top surface of the substrate, wherein each of the plurality of semiconductor patterns includes a source region having a first conductivity type, a drain region having a second conductivity type, and an intrinsic region between the source region and the drain region; first and second word lines that surround the intrinsic regions of the plurality of semiconductor patterns and extend in the first direction; a plurality of ferroelectric patterns between the plurality of semiconductor patterns and the first and second word lines, the plurality of ferroelectric patterns surrounding the intrinsic regions of the semiconductor patterns; a plurality of gate dielectric patterns between respective ones of the plurality of ferroelectric patterns and the plurality of semiconductor patterns; a plurality of bit lines that extend along a second direction parallel to the top surface of the substrate and are connected to one of the source or the drain regions of the plurality of semiconductor patterns; and a plurality of source lines that extend along the first direction and are connected to another of the source or drain regions of the plurality of semiconductor patterns.

Alternatively or additionally according to some example embodiments, a semiconductor memory device may include a substrate; a plurality of first bit lines that are stacked on the substrate and extend in a first direction that is parallel to a top surface of the substrate; a plurality of second bit lines that are stacked on the substrate and extend in the first direction; a plurality of source lines between respective ones of the plurality of first and second bit lines, the plurality of source lines extending in a second direction that is perpendicular to the top surface of the substrate; a plurality of first memory cells at intersections between the plurality of first bit lines and the plurality of source lines; and a plurality of second memory cells at intersections between the plurality of second bit lines and the plurality of source lines. Each of the plurality of first and second memory cells may include a semiconductor pattern that has a major axis in a third direction parallel to the top surface of the substrate, wherein the semiconductor pattern includes a source region having a first conductivity type, a drain region having a second conductivity type, and an intrinsic region between the source region and the drain region; first and second gate electrodes that surround the intrinsic region of the semiconductor pattern; a ferroelectric pattern between the semiconductor pattern and the first and second gate electrodes; and a gate dielectric pattern between the ferroelectric pattern and the semiconductor pattern.

Details of these and other example embodiments are included in the description and drawings.

### BRIEF DESCRIPTION OF DRAWINGS

FIG. 1 illustrates a block diagram showing a semiconductor memory device according to some example embodiments.

FIGS. 2A and 2B illustrate perspective views showing a semiconductor memory device according to some example embodiments.

FIG. 3 illustrates a perspective view showing a unit memory cell of a semiconductor memory device according to some example embodiments.

FIG. 4 illustrates a cross-sectional view showing a unit memory cell of a semiconductor memory device according to some example embodiments.

FIG. 5A illustrates a band diagram when voltages are applied to a drain, a source, and a gate in a cross-section taken along line I-I′ of FIG. 4.

FIGS. 5B and 5C illustrate band diagrams when voltages are applied to a drain, a source, and a gate of a memory device in a cross-section taken along line II-II′ of FIG. 4.

FIG. 6 illustrates a perspective view showing a memory cell array of a semiconductor memory device according to some example embodiments.

FIGS. 7A, 7B, and 7C illustrate enlarged views of section P depicted in FIG. 6, showing a unit memory cell of a semiconductor memory device according to some example embodiments.

FIG. 8 illustrates a plan view showing a semiconductor memory device according to some example embodiments.

FIG. 9A illustrates a cross-sectional view taken along line A-A′ of FIG. 8, showing a semiconductor memory device according to some example embodiments.

FIG. 9B illustrates a cross-sectional view taken along line B-B′ of FIG. 8, showing a semiconductor memory device according to some example embodiments.

FIG. 10 illustrates a plan view showing a semiconductor memory device according to some example embodiments.

FIG. 11A illustrates a cross-sectional view taken along line A-A′ of FIG. 10, showing a semiconductor memory device according to some example embodiments.

FIG. 11B illustrates a cross-sectional view taken along line B-B′ of FIG. 10, showing a semiconductor memory device according to some example embodiments.

FIGS. 12A, 13A, 14A, 15A, 16A, 17A, 18A, and 19A illustrate plan views showing a method of fabricating a semiconductor memory device according to some example embodiments.

FIGS. 12B, 13B, 14B, 15B, 16B, 17B, 18B, and 19B illustrate cross-sectional views taken along lines A-A′ and B-B′ of FIGS. 12A, 13A, 14A, 15A, 16A, 17A, 18A, and 19A, showing a method of fabricating a semiconductor memory device according to some example embodiments.

FIGS. 20A and 20B illustrate diagrams showing an operation in a volatile memory mode of a semiconductor memory device according to some example embodiments.

FIGS. 21A and 21B illustrate diagrams showing an operation in a non-volatile memory mode of a semiconductor memory device according to some example embodiments.

### DETAILED DESCRIPTION OF VARIOUS EXAMPLE EMBODIMENTS

It will be hereinafter described in detail a semiconductor memory device according to the present inventive concepts in conjunction with the accompanying drawings.

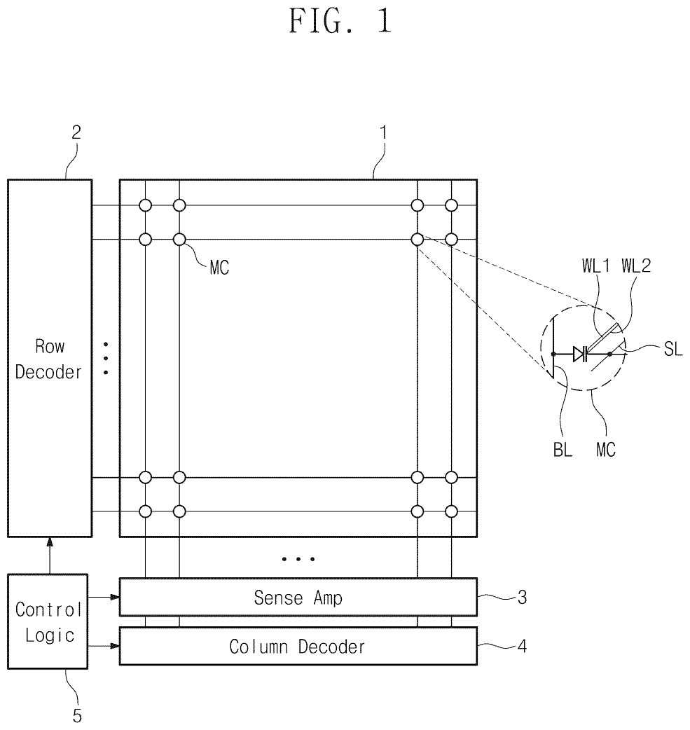

FIG. 1 illustrates a block diagram showing a semiconductor memory device according to some example embodiments.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC that are arranged three-dimensionally. The memory cell array 1 may include a plurality of first conductive lines BL and a plurality of second conductive lines SL that intersect the first conductive lines BL, and may also include a plurality of memory cells MC that are correspondingly disposed at intersections between the first and second conductive lines BL and SL. The memory cell array 1 may additionally or alternatively include one or more dummy memory cells (not shown) and/or one or more redundancy memory cells (not shown).

According to some example embodiments, based on a voltage condition, each of the memory cells MC may operate in a volatile memory mode, or a non-volatile memory mode. Such semiconductor device may be fabricated at low costs at least because or partly because a memory unit and a logic element unit are integrated together with each other on one chip. Alternatively or additionally, when an electronic device according to some example embodiment is applied to an application field, such as neuromorphic device, in which a large amount of data is successively transferred between a memory unit and a logic element unit, it may be possible to achieve one or more of efficiency improvement, speed increase, power consumption reduction, and so forth.

As used herein, the term volatile memory may indicate a memory having access speeds and power consumption similar to that of dynamic random access memory (DRAM) and/or static random access memory (SRAM). In some example embodiments, when the power is reduced or turned off to the memory cell MC acting as a volatile memory cell, data stored in the memory cell acting as a volatile memory cell may not be retained. Example embodiments are not limited thereto.

Each memory cell MC may include first and second gate electrodes, a source electrode, and a drain electrode. One of the source or the drain electrode, e.g., the drain electrode, of each memory cell MC may be connected to the first conductive line BL (e.g., a bit line), and the other of the source electrode or the drain electrode, e.g., the source electrode, of each memory cell MC may be connected to the second conductive line SL (e.g., a source line). The first gate electrode of each memory cell MC may be connected to a first word line WL1, and the second gate electrode of each memory cell MC may be connected to a second word line WL2.

The row decoder 2 may decode an address that is input from an external source, such as from a host, and may select one of the source lines SL of the memory cell array 1. The address decoded in the row decoder 2 may be provided to a row driver (not shown), and in response to control of control circuits, the row driver may provide a certain voltage, e.g., a voltage greater than a threshold voltage, to each of the source lines SL.

In response to an address that is decoded from the column decoder 4, the sense amplifier 3 may detect and amplify a voltage difference between a selected bit line BL and a reference or complementary bit line, and may then output the amplified voltage difference.

The column decoder 4 may provide a data delivery path between the sense amplifier 3 and an external device (e.g., a memory controller). The column decoder 4 may decode an address that is externally input and may select one of the bit lines BL.

The control logic 5 may generate control signals that control operations to write data to the memory cell array 1 and/or to read data from the memory cell array 1.

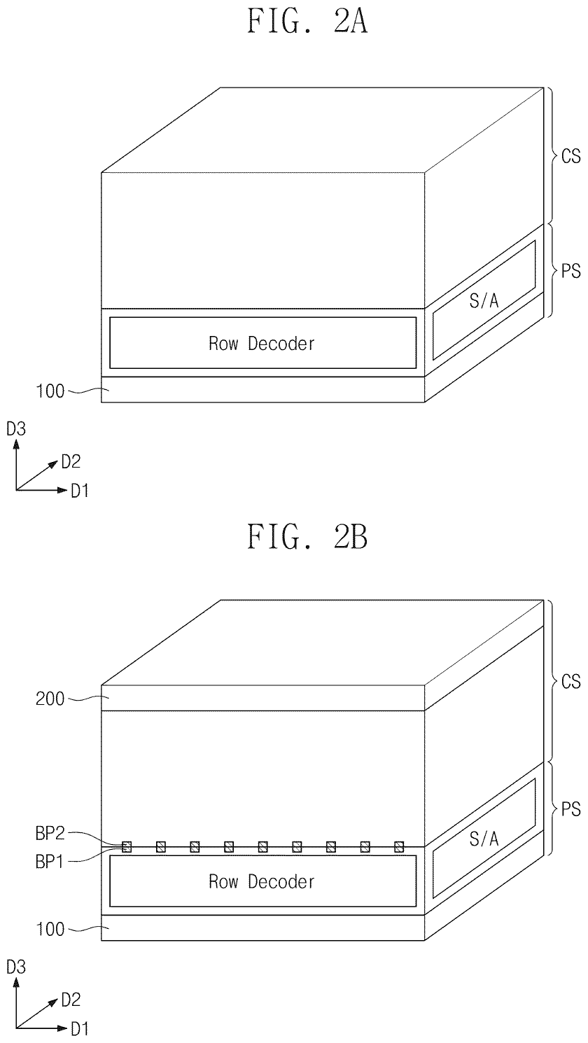

FIGS. 2A and 2B illustrate perspective views showing a semiconductor memory device according to some example embodiments.

Referring to FIGS. 2A and 2B, a semiconductor memory device may include a cell array structure CS and a peripheral circuit structure PS, e.g., on the cell array structure CS.

Referring to FIG. 2A, the peripheral circuit structure PS may include core/peripheral circuits formed on a substrate 100. The core/peripheral circuits may include the row and column decoders (see 2 and 4 of FIG. 1), the sense amplifier (see 3 of FIG. 1), and the control logics (see 5 of FIG. 1).

The cell array structure CS may be disposed on the peripheral circuit structure PS, and may include a memory cell array including memory cells that are three-dimensionally arranged on the peripheral circuit structure PS. The memory cell may include horizontal patterns that are sequentially stacked on a substrate, vertical patterns that vertically run across the horizontal patterns, and memory elements between the horizontal and vertical patterns.

Referring to FIG. 2B, the peripheral circuit structure PS may be formed on a substrate 100, and the cell array structure CS may be formed on a second substrate 200 (e.g., a semiconductor substrate). The periphery circuit PS may include one or more transistors, such as two-dimensional and/or three-dimensional transistors. The peripheral circuit structure PS may include first bonding pads BP1 electrically connected to the core/peripheral circuits, and the cell array structure CS may include second bonding pads BP2 electrically connected to memory cells. In this case, the first bonding pads BP1 and the second bonding pads BP2 may be connected to each other by a bonding method to electrically connect the peripheral circuit structure PS to the cell array structure CS. For example, the bonding method may indicate a method for electrically connecting a bonding metal pad formed on an uppermost metal layer of an upper chip to a bonding metal pad formed on an uppermost metal layer of a lower chip. For example, when the first and second bonding pads BP1 and BP2 are formed of copper (Cu), the bonding method may be a Cu-to-Cu bonding method, and alternatively the first and second bonding pads BP1 and BP2 may be formed of aluminum (Al) and/or tungsten (W).

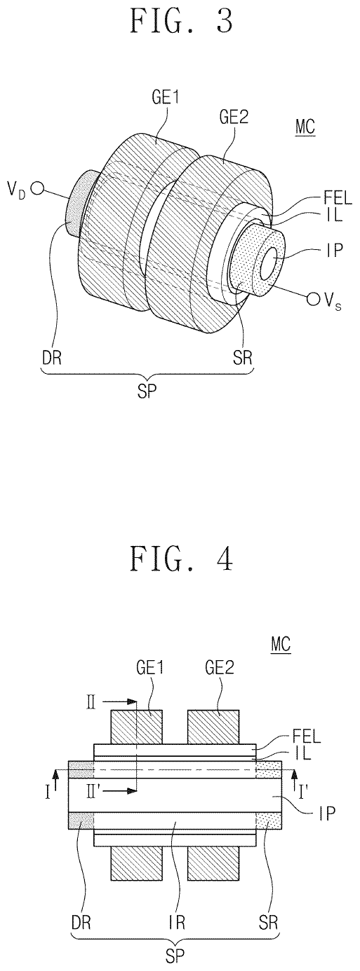

FIG. 3 illustrates a perspective view showing a unit memory cell of a semiconductor memory device according to some example embodiments concept. FIG. 4 illustrates a cross-sectional view showing a unit memory cell of a semiconductor memory device according to some example embodiments.

Referring to FIGS. 3 and 4, a unit memory cell according to various example embodiments may include a semiconductor pattern SP, first and second gate electrodes GE1 and GE2, a ferroelectric pattern FEL, and a gate dielectric pattern IL.

The semiconductor pattern SP may include a drain region DR, a source region SR, and an intrinsic region IR between the drain and source regions DR and SR. The source region SR may have a first conductivity type (e.g., n-type), and the drain region DR may have a second conductivity type (e.g., p-type) opposite to the first conductivity type. For example, the source region SR may be doped with an n-type dopant such as but not limited to arsenic and/or phosphorus, and the drain region DR may be doped with a p-type dopant such as but not limited to boron.

In some example embodiments, a conductivity type of the source region SR and/or a conductivity type of the drain region DR may be based on a concentration of primary dopants included in the respective one of the source region or the drain region. There may or may not be counter-doping of various impurities. In some example embodiments, the source region SR may include n-type dopants and no p-type dopants, or may include n-type dopants at a much higher doping concentration than p-type dopants. Alternatively or additionally, the drain region DR may include p-type dopants and no n-type dopants, or may include p-type dopants at a much higher concentration than n-type dopants. In some example embodiments, the intrinsic region IR may not include any n-type or p-type dopants, or may include n-type dopants at a much lower concentration than that of the source region SR. Alternatively or additionally, the intrinsic region IR may include p-type dopants at a much lower concentration than that of the drain region DR.

A drain voltage VD may be applied to the drain region DR of the semiconductor pattern SP, and a source voltage Vs may be applied to the source region SR of the semiconductor pattern SP.

The semiconductor pattern SP may include one or more of silicon (Si), germanium (Ge), and silicon-germanium (SiGe). For example, the semiconductor pattern SP may be formed of polycrystalline silicon. Alternatively or additionally, the semiconductor pattern SP may include either an oxide semiconductor, such as one or more of indium gallium zinc oxide (IGZO), indium tungsten oxide (IWO), zinc oxide (ZnO), indium tin zinc oxide (ITZO), and BaSnO or a two-dimensional material, such as MoS₂ and/or WSe₂, or both an oxide semiconductor and a two-dimensional material.

The first and second gate electrodes GEL and GE2 may be disposed on the intrinsic region IR of the semiconductor pattern SP. The first and second gate electrodes GE1 and GE2 may be spaced apart from each other between the source and drain regions SR and DR. For example, a gate-all-around structure may be provided in which the first and second gate electrodes GE1 and GE2 completely surround the intrinsic region IR of the semiconductor pattern SP.

For example, the first and second gate electrodes GEL and GE2 may include one of doped semiconductor materials (doped silicon and/or doped germanium, etc.), conductive metal nitrides (titanium nitride and/or tantalum nitride, etc.), metals (one or more of tungsten, titanium, tantalum, etc.), and metal-semiconductor compounds (one or more of tungsten silicide, cobalt silicide, titanium silicide, etc.).

The ferroelectric pattern FEL may be disposed between the semiconductor pattern SP and the first and second gate electrodes GEL and GE2. The ferroelectric pattern FEL may be provided as a data storage layer of the memory cell.

The ferroelectric pattern FEL may surround a sidewall of the semiconductor pattern SP. The ferroelectric pattern FEL may have a macaroni shape or a pipe shape whose opposite ends are opened.

The ferroelectric pattern FEL may have a spontaneous dipole (electric dipole), or spontaneous polarization, due to a non-centrosymmetric charge distribution in each memory cell. The ferroelectric pattern FEL may have a dipole-induced remnant polarization even in the presence of no external electric field. In addition, a polarization direction may be switched in domain units by an external electric field.

For example, the ferroelectric pattern FEL may have a positive or negative polarization state, and the polarization state may be changed due to an electric field applied to the ferroelectric pattern FEL during a program operation. The ferroelectric pattern FEL may maintain its polarization state even when a power is interrupted, and thus based on voltages applied to the first and second gate electrodes GE1 and GE2, a semiconductor memory device may operate as a non-volatile memory device.

In addition, when a semiconductor memory device operates as a volatile memory device, the speed of switching of polarization state in the ferroelectric pattern FEL may be so fast that there may be a reduction in standby current for data maintenance. Accordingly, a semiconductor memory device may decrease in standby current, and/or may operate at a lower rate of power consumption.

Moreover, a single-layered ferroelectric pattern FEL may be used as a data storage layer in the unit memory cell, and as a result, it may be advantageous to increase integration of a semiconductor memory device.

The gate dielectric pattern IL may be interposed between the ferroelectric pattern FEL and the semiconductor pattern SP. The gate dielectric pattern IL may include a high-k dielectric layer having a dielectric constant greater than that of silicon oxide, a silicon oxide layer, a silicon nitride layer, a silicon oxynitride layer, or a combination thereof. For example, the high-k dielectric layer may include at least one selected from hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively or additionally, the unit memory cell may further include a dielectric pillar IP, and the semiconductor pattern SP may surround the dielectric pillar IP. The dielectric pillar IP may be a tetragonal pillar or a circular pillar. The dielectric pillar IP may include, for example, at least one selected from a silicon oxide layer, a silicon oxynitride layer, and a silicon nitride layer. When the semiconductor pattern SP surrounds the dielectric pillar IP, on a sidewall of the dielectric pillar IP, a thickness of the semiconductor pattern SP may be less than a diameter of the dielectric pillar IP.

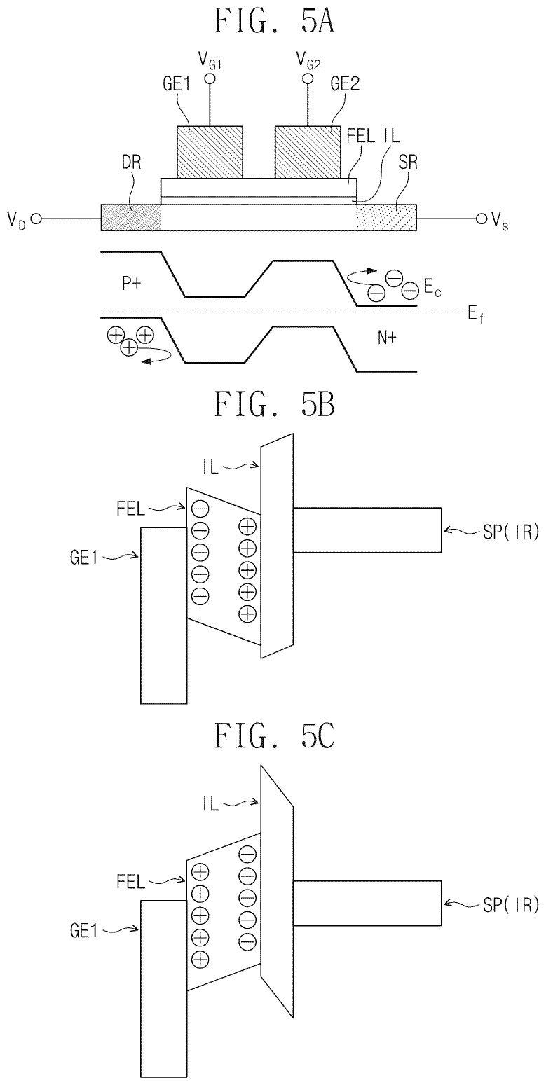

FIG. 5A illustrates a band diagram (a Fermi band diagram) when voltages are applied to a drain, a source, and a gate in a cross-section taken along line I-I′ of FIG. 4.

Referring to FIG. 5A, the first gate electrode GE1 and the second gate electrode GE2 may be respectively provided with a first gate voltage V_{G1} and a second gate voltage V_{G2} that are complementary to each other, e.g., of opposite signs from each other. In an operation of a volatile memory mode, for example, the first gate voltage V_{G1} and the second gate voltage V_{G2} may be about −3 V and 3 V, respectively.

The complimentary first and second gate voltages V_{G1} and V_{G2} may be applied to change an energy level of the intrinsic region IR adjacent to the first gate electrode GE1 and an energy level of the intrinsic region IR adjacent to the second gate electrode GE2.

When the first gate electrode GE1 is provided with the first gate voltage V_{G1}, e.g., a positive voltage, a portion of the intrinsic region IR may exhibit properties of an n-type semiconductor material. When the second gate electrode GE2 is provided with the second gate voltage V_{G2}, e.g., a negative voltage, another portion of the intrinsic region IR may exhibit properties of a p-type semiconductor material. Therefore, an energy barrier may be formed in the intrinsic region IR. For example, a p-i-n structure of the semiconductor pattern SP may be changed into a p-n-p-n structure. In such a case, the complementary voltages applied to the first and second gate electrodes GEL and GE2 may cause a semiconductor memory device to operate as a thyristor. As such, in a state with an energy level of the p-n-p-n structure, when the drain voltage VD (e.g., about 1 V) is applied to a bit line connected to the drain region DR, an energy barrier between the drain region DR and the intrinsic region IR may increase such that almost no drain current may flow through the semiconductor pattern SP.

FIGS. 5B and 5C illustrate band (or Fermi) diagrams when voltages are applied to a drain, a source, and a gate of a memory device in a cross-section taken along line II-II′ of FIG. 4.

FIGS. 5B and 5C show an energy band due to remnant polarization in the ferroelectric pattern FEL when a certain voltage is applied to the first gate electrode GE1 when viewed in a cross-section taken along line II-II′ of FIG. 4.

A polarization state of the ferroelectric pattern FEL may be determined based on a difference in voltage between the intrinsic region IR of the semiconductor pattern SP and one of the first and second gate electrodes GE1 and GE2.

A polarization direction of the ferroelectric pattern FEL may be changed due to a difference in voltage between the intrinsic region IR and one of the first and second gate voltages V_{G1} and V_{G2} applied to the first and second gate electrodes GE1 and GE2. The difference in voltage between the intrinsic region IR and one of the first and second gate voltages V_{G1} and V_{G2} may be equal to or greater than a minimum voltage required for changing polarization of the ferroelectric pattern FEL.

Referring to FIG. 5B, when the ferroelectric pattern FEL is in a first polarization state, a difference in potential between the first gate electrode GE1 and the semiconductor pattern SP may induce polarization in which positive charges in the ferroelectric pattern FEL are located adjacent to the semiconductor pattern SP.

As shown in FIG. 5B, the positive charges adjacent to the semiconductor pattern SP may cause a bending of energy bands of the ferroelectric pattern FEL, the gate dielectric pattern IL, and the intrinsic region IR.

Referring to FIG. 5C when the ferroelectric pattern FEL is in a second polarization state, a difference in potential between the first gate electrode GE1 and the semiconductor pattern SP may induce polarization in which negative charges in the ferroelectric pattern FEL are located adjacent to the semiconductor pattern SP. As shown in FIG. 5C, the negative charges adjacent to the semiconductor pattern SP may cause a bending of energy bands of the ferroelectric pattern FEL, the gate dielectric pattern IL, and the intrinsic region IR.

An electric potential in the vicinity of an interface between the gate dielectric pattern IL and the intrinsic region IR may be changed due to a direction of remnant polarization in the ferroelectric pattern FEL, and therefore when a potential difference is applied between the source region SR and the drain region DR, a value of current that flows may be changed in accordance with the direction of remnant polarization. This phenomenon may be used to read data stored in the ferroelectric pattern FEL.

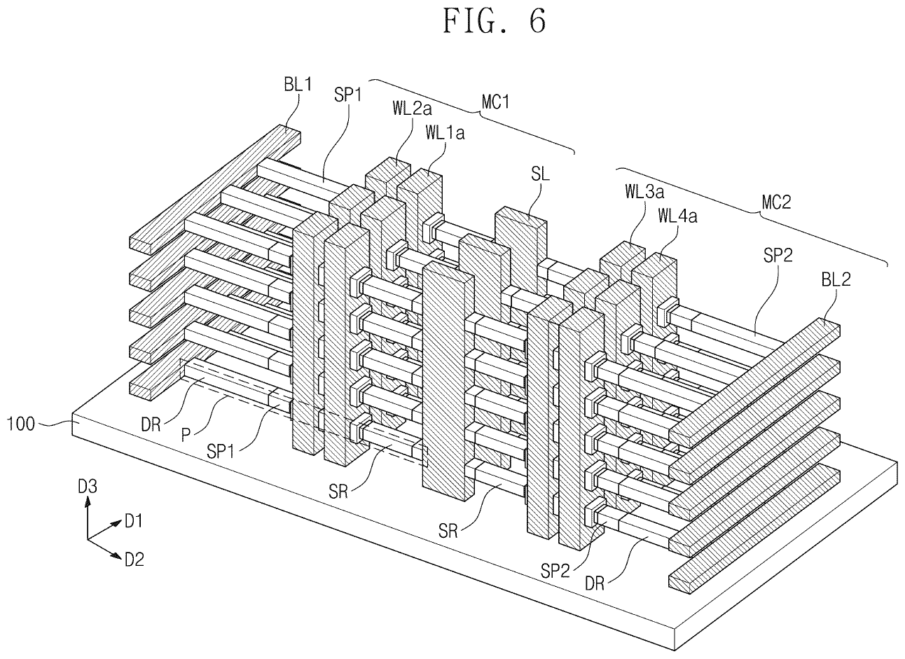

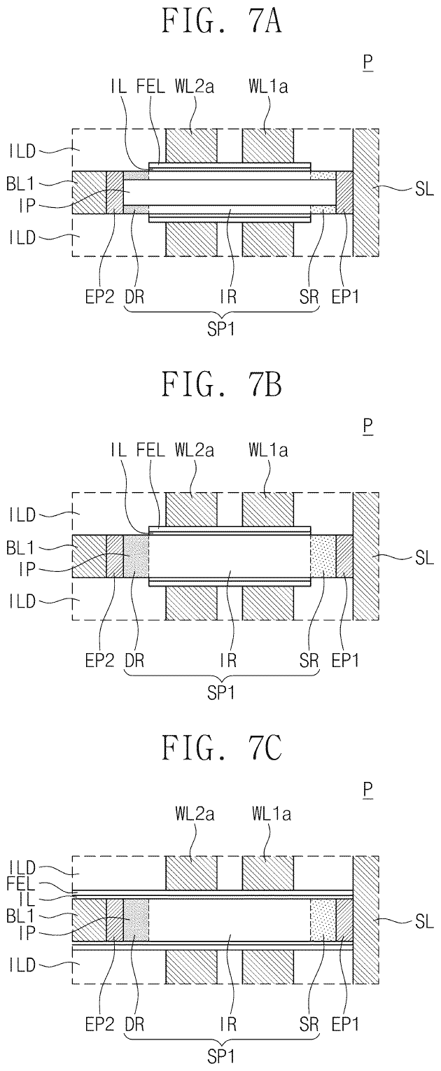

FIG. 6 illustrates a perspective view showing a memory cell array of a semiconductor memory device according to some example embodiments. FIGS. 7A, 7B, and 7C illustrate enlarged views of section P depicted in FIG. 6, showing a unit memory cell of a semiconductor memory device according to some example embodiments.

Referring to FIG. 6, a substrate 100 may be provided thereon with bit lines BL1 and BL2 and the source lines SL that intersect the bit lines BL1 and BL2.

The substrate 100 may be or may include a semiconductor substrate including a semiconductor material or a dielectric substrate including a dielectric material. For example, the semiconductor substrate may be a silicon substrate, a germanium substrate, or a silicon-germanium substrate. Alternatively or additionally, the dielectric substrate may be or may include a ceramic substrate including a metal compound, such as aluminum oxide.

The bit lines BL1 and BL2 may extend along a first direction D1 parallel to a top surface of the substrate 100, and may be stacked along a third direction D3 perpendicular to the top surface of the substrate 100. According to various example embodiments, the bit lines BL1 and BL2 may include first bit lines BL1 on one side of the source lines SL and second bit lines BL2 on another side of the source lines SL. For example, the second bit lines BL2 may be spaced apart in a second direction D2 from the first bit lines BL1 across the source lines SL.

The source lines SL may extend along the third direction D3 perpendicular to the top surface of the substrate 100, while running across the first and second bit lines BL1 and BL2. The source lines SL may be spaced apart from each other in the first direction D1 on the substrate 100.

The first and second bit lines BL1 and BL2 and the source lines SL may include, for example, one of doped semiconductor materials (one or more of doped silicon, doped germanium, etc.), conductive metal nitrides (one or more of titanium nitride, tantalum nitride, etc.), metals (one or more of tungsten, titanium, tantalum, etc.), and metal-semiconductor compounds (one or more of tungsten silicide, cobalt silicide, titanium silicide, etc.).

Memory cells MC1 and MC2 may be correspondingly provided at intersections between the source lines SL and the first and second bit lines BL1 and BL2. For example, the memory cells MC1 and MC2 may be three-dimensionally arranged on the substrate 100.

According to some example embodiments, the memory cells MC1 and MC2 may include first memory cells MC1 that are correspondingly provided at the intersections between the first bit lines BL1 and the source lines SL and second memory cells MC2 that are correspondingly provided at the intersections between the second bit lines BL2 and the source lines SL. The source lines SL may be shared by the first and second memory cells MC1 and MC2 that are adjacent to each other in the second direction D2. One of the first and second memory cells MC1 and MC2 may be selected by one selected from the first and second bit lines BL1 and BL2 and one selected from the source lines SL.

Each of the first memory cells MC1 may include a first semiconductor pattern SP1, and each of the second memory cells MC2 may include a second semiconductor pattern SP2. Each of the first and second semiconductor patterns SP1 and SP2 may have a major axis or an extension axis in the second direction D2.

The first and second semiconductor patterns SP1 and SP2 of the first and second memory cells MC1 and MC2 may be spaced apart from each other in the first direction D1, the second direction D2, and the third direction D3. For example, the first and second semiconductor patterns SP1 and SP2 may be three-dimensionally arranged on the substrate 100. The first and second semiconductor patterns SP1 and SP2 may include at least one selected from silicon and germanium. Alternatively or additionally, the first and second semiconductor patterns SP1 and SP2 may include an oxide semiconductor material.

Referring to FIGS. 7A, 7B, and 7C, as discussed above, each of the first semiconductor patterns SP1 may include a source region SR having a first conductivity type (e.g., n-type), a drain region DR having a second conductivity type (e.g., p-type), and an intrinsic region IR between the source region SR and the drain region DR. The source region SR may be doped with an n-type dopant such as but not limited to arsenic and/or phosphorus, and the drain region DR may be doped with a p-type dopant such as but not limited to boron. When viewed in the second direction D2, a length of the source region SR may be different from that of the drain region DR. Each of the second semiconductor patterns SP2 may also be configured identically or similarly to the first semiconductor pattern SP1.

Referring to FIG. 7A, each of the first semiconductor patterns SP1 may have a pipe shape which surrounds a dielectric pillar IP and whose opposite ends are opened. Referring to FIGS. 7B and 7C, each of the first and second semiconductor patterns SP1 and SP2 may have a tetragonal shape, a polygonal shape, or a circular shape.

Referring to FIGS. 6 and 7A, the first bit lines BL1 may be correspondingly connected to the drain regions DR arranged along the first direction D1 of the first semiconductor patterns SP1. The second bit lines BL2 may be correspondingly connected to the drain regions DR arranged along the first direction D1 of the second semiconductor patterns SP2. The source lines SL may be correspondingly connected to the source regions SR arranged along the third direction D3 of the first and second semiconductor patterns SP1 and SP2. The source lines SL may be spaced apart and separated from each other in the first direction D1. As shown in FIG. 6, the first and second semiconductor patterns SP1 and SP2 may be disposed mirror-symmetrically about the source lines SL.

A first electrode EP1 may be interposed between the source line SL and each of the first and semiconductor patterns SP1 and SP2, and a second electrode EP2 may be interposed between each of the first and second semiconductor patterns SP1 and SP2 and a corresponding one of the first and second bit lines BL1 and BL2. The first and second electrodes EP1 and EP2 may include, for example, at least one selected from W, Ti, Al, Cu, C, CN, TIN, TiAIN, TiSiN, TiCN, WN, CoSiN, WSIN, TaN, TaCN, and TaSiN.

First and second word lines WL1a to WL1d and WL2a to WL2d may be disposed on the substrate 100 between the first bit lines BL1 and the source lines SL. The first and second word lines WL1a to WL1d and WL2a to WL2d may extend in the third direction D3 perpendicular to the top surface of the substrate 100. The first word lines WL1a to WL1d may be spaced apart and separated from each other in the first direction D1. The second word lines WL2a to WL2d may be spaced apart and separated from each other in the first direction D1.

The first and second word lines WL1a to WL1d and WL2a to WL2d may be spaced apart from each other in the second direction D2. The first and second word lines WL1a to WL1d and WL2a to WL2d may correspondingly surround the first semiconductor patterns SP1 that are stacked in the third direction D3. As shown in FIGS. 7A-7C, each of the first and second word lines WL1a to WL1d and WL2a to WL2d may be adjacent to the intrinsic region IR of one of the first semiconductor patterns SP1.

Third and fourth word lines WL3a to WL3d and WL4a to WL4d may be disposed on the substrate 100 between the second bit lines BL2 and the source lines SL. The third and fourth word lines WL3a to WL3d and WL4a to WL4d may extend in the third direction D3. The third word lines WL3a to WL3d may be spaced apart and separated from each other in the first direction D1. The fourth word lines WL4a to WL4d may be spaced apart and separated from each other in the first direction D1.

The third and fourth word lines WL3a to WL3d and WL4a to WL4d may be spaced apart from each other in the second direction D2. The third and fourth word lines WL3a to WL3d and WL4a to WL4d may correspondingly surround the second semiconductor patterns SP2 that are stacked in the third direction D3. As shown in FIGS. 7A-7C, each of the third and fourth word lines WL3a to WL3d and WL4a to WL4d may be adjacent to the intrinsic region IR of one of the second semiconductor patterns SP2.

The first, second, third, and fourth word lines WL1a to WL1d, WL2a to WL2d, WL3a to WL3d, and WL4a to WL4d may include, for example, one, or more than one, of doped semiconductor materials (doped silicon and/or doped germanium, etc.), conductive metal nitrides (titanium nitride and/or tantalum nitride, etc.), metals (one or more of tungsten, titanium, tantalum, etc.), and metal-semiconductor compounds (one or more of tungsten silicide, cobalt silicide, titanium silicide, etc.).

Referring to FIGS. 6, 7A, 7B, and 7C, a ferroelectric pattern FEL may be interposed between the first and second word lines WL1a to WL1d and WL2a to WL2d and the first semiconductor patterns SP1 and between the third and fourth word lines WL3a to WL3d and WL4a to WL4d and the second semiconductor patterns SP2. The ferroelectric pattern FEL may surround a sidewall of each of the first and second semiconductor patterns SP1 and SP2. The ferroelectric pattern FEL may have a macaroni shape or a pipe shape whose opposite ends are opened.

Referring to FIGS. 7A and 7B, the ferroelectric pattern FEL and a gate dielectric pattern IL may surround the intrinsic region IR of each of the first and second semiconductor patterns SP1 and SP2, and may be spaced apart from the source and drain regions SR and DR. Alternatively, referring to FIG. 7C, the ferroelectric pattern FEL and the gate dielectric pattern IL may completely surround the sidewall of each of the first and second semiconductor patterns SP1 and SP2. The ferroelectric pattern FEL and the gate dielectric pattern IL may have a length in the second direction D2 substantially the same as that of the first and second semiconductor patterns SP1 and SP2. One side of each of the ferroelectric pattern FEL and the gate dielectric pattern IL may be in contact with the first bit line BL1 or the second bit line BL2, and another side of each of the ferroelectric pattern FEL and the gate dielectric pattern IL may be in contact with the source line SL.

The gate dielectric pattern IL may be interposed between the ferroelectric pattern FEL and one of the first and second semiconductor patterns SP1 and SP2. The gate dielectric pattern IL may surround the sidewall of each of the first and second semiconductor patterns SP1 and SP2. For example, as in the ferroelectric pattern FEL, the gate dielectric pattern IL may have a macaroni shape or a pipe shape whose opposite ends are opened.

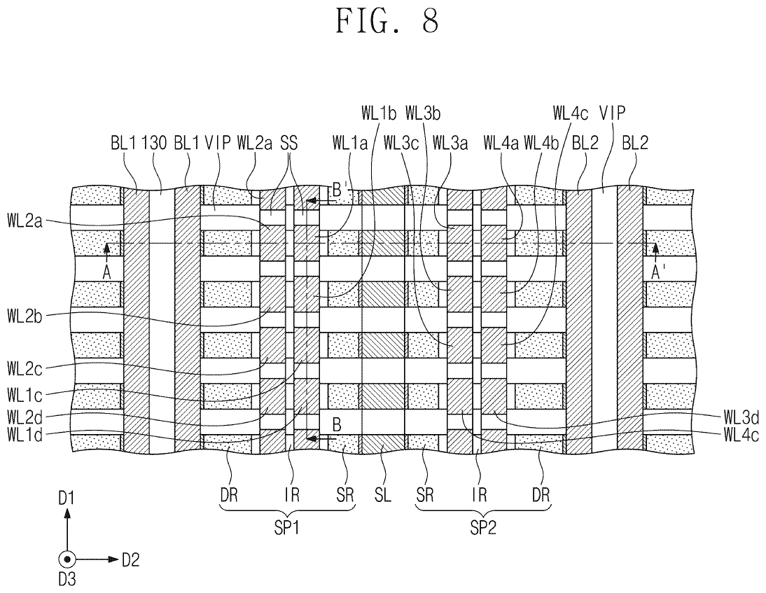

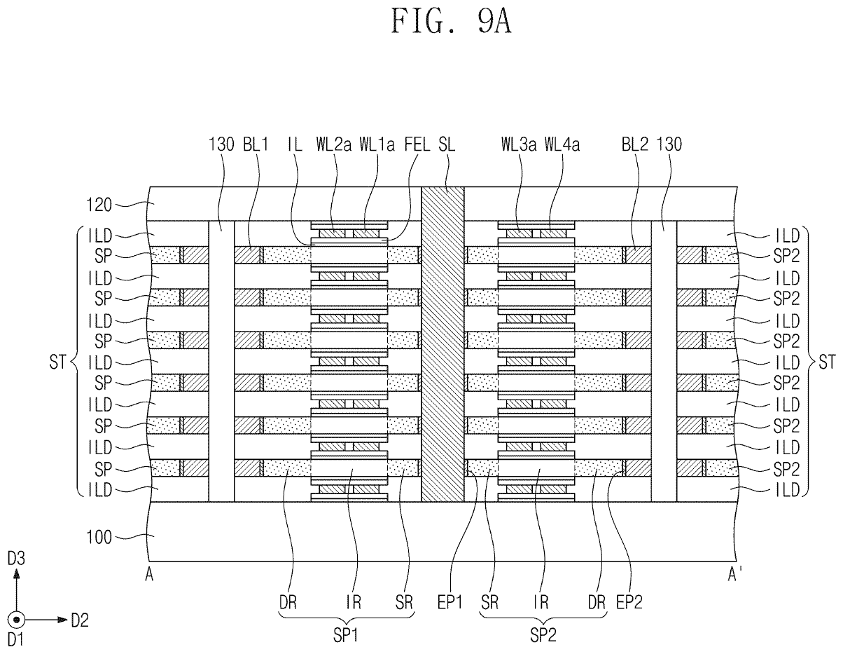

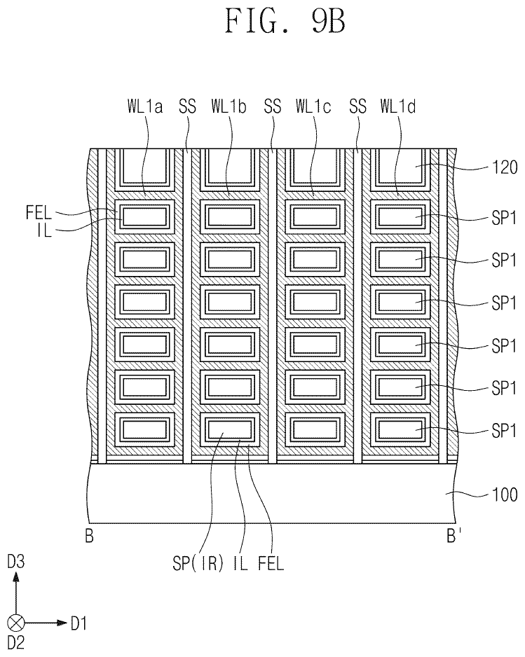

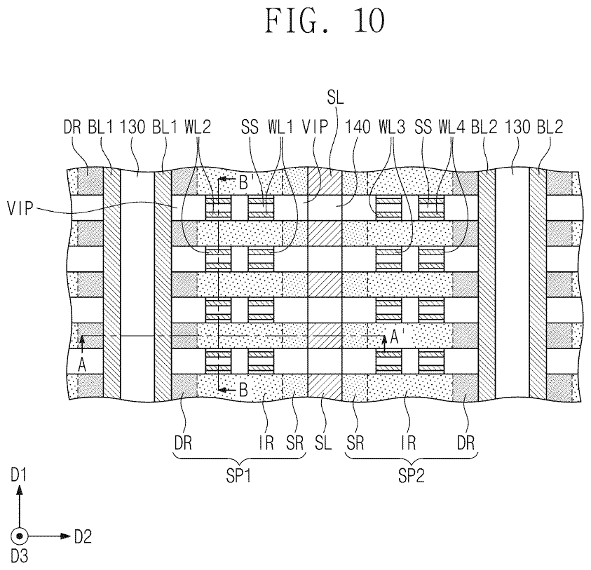

FIG. 8 illustrates a plan view showing a semiconductor memory device according to some example embodiments. FIG. 9A illustrates a cross-sectional view taken along line A-A′ of FIG. 8, showing a semiconductor memory device according to some example embodiments. FIG. 9B illustrates a cross-sectional view taken along line B-B′ of FIG. 8, showing a semiconductor memory device according to some example embodiments.

Referring to FIGS. 8, 9A, and 9B, stack structures ST may be disposed on a substrate 100. For example, the substrate 100 may be or include, or be included in, a silicon substrate or a silicon-on-insulator (SOI) substrate. The substrate 100 may further include a thin layer formed on the semiconductor substrate. For example, the substrate 100 may be or include, or be included in, a ceramic substrate including a metal compound, such as aluminum oxide.

The stack structures ST may be disposed spaced apart from each other along a first direction D1 and a second direction D2 on the substrate 100.

Each of the stack structures ST may include interlayer dielectric layers ILD and ones of first and second semiconductor patterns SP1 and SP2 that are alternately stacked along a third direction D3 perpendicular to a top surface of the substrate 100.

The first semiconductor patterns SP1 may be spaced apart from each other along the first direction D1 and the third direction D3 between first bit lines BL1 and source lines SL. The first semiconductor patterns SP1 stacked in the third direction D3 may be connected to a corresponding source line SL. The first semiconductor patterns SP1 located at the same level may be connected to the first bit line BL1. The first semiconductor patterns SP1 adjacent to each other in the third direction D3 may be separated from each other by the interlayer dielectric layers ILD interposed therebetween. The first semiconductor patterns SP1 adjacent to each other in the first direction D1 may be separated from each other by vertical dielectric patterns VIP interposed therebetween.

The second semiconductor patterns SPs may be spaced apart from each other along the first direction D1 and the third direction D3 between second bit lines BL2 and the source lines SL. The second semiconductor patterns SP2 located at the same level may be correspondingly connected to the second bit lines BL2 and may be connected in common to a corresponding one of the source lines SL.

The second semiconductor patterns SP2 adjacent to each other in the third direction D3 may be separated from each other by the interlayer dielectric layers ILD interposed therebetween. The second semiconductor patterns SP2 adjacent to each other in the first direction D1 may be separated from each other by vertical dielectric patterns VIP interposed therebetween.

The first and second semiconductor patterns SP1 and SP2 may include a polycrystalline silicon layer or a monocrystalline silicon layer. The interlayer dielectric layers ILD may be at least one selected from a silicon oxide layer, a silicon oxynitride layer, and a silicon nitride layer.

In each stack structure ST, as discussed above, each of the first and second semiconductor patterns SP1 and SP2 may have a shape that has a major axis or an extension axis in the second direction D2. Each of the first and second semiconductor patterns SP1 and SP2 may include a source region SR, a drain region DR spaced apart from the source region SR, and an intrinsic region IR between the source and drain regions SR and DR. The source and drain regions SR and DR may have their conductivity types opposite to each other. Each of the first and second semiconductor patterns SP1 and SP2 may be locally provided between a pair of vertical dielectric patterns VIP that neighbor each other in the first direction D1 and between a pair of interlayer dielectric layers ILD that neighbor each other in the third direction D3.

The first and second semiconductor patterns SP1 and SP2 may be disposed symmetrically to each other across the source lines SL. For example, the source regions SR of the first semiconductor patterns SP1 or the second semiconductor patterns SP2 may be connected in common to a corresponding source line SL. The drain regions DR of the first semiconductor patterns SP1 may be correspondingly connected to the first bit lines BL1. The drain regions DR of the second semiconductor patterns SP2 may be correspondingly connected to the second bit lines BL2.

The first and second bit lines BL1 and BL2 may extend in the first direction D1. The first and second bit lines BL1 and BL2 may be interposed between the interlayer dielectric layers ILD that neighbor each other in the third direction D3. Lowermost ones of the interlayer dielectric layers ILD may be interposed between the substrate 100 and lowermost first and second bit lines BL1 and BL2.

The source lines SL may extend along the third direction D3 from the top surface of the substrate 100, and may be spaced apart from each other in the first direction D1. The source lines SL may run across the first and second bit lines BL1 and BL2. The source lines SL may have substantially the same length in the third direction D3. The source lines SL may be disposed between the first and second semiconductor patterns SP1 and SP2 that are adjacent to each other in the second direction D2.

The first and second bit lines BL1 and BL2 and the source lines SL may include one or more of metal (e.g., one or more of copper, tungsten, or aluminum) and metal nitride (e.g., one or more of tantalum nitride, titanium nitride, or tungsten nitride). The interlayer dielectric layers ILD may include silicon nitride and/or silicon oxide.

The vertical dielectric patterns VIP may be correspondingly disposed between the stack structures ST that are adjacent to each other in the first direction D1. The vertical dielectric patterns VIP may be spaced apart from each other in the first direction D1, while extending along the third direction D3 from the top surface of the substrate 100. The vertical dielectric patterns VIP may be adjacent to the source and drain regions SR and DR of the first and second semiconductor patterns SP1 and SP2. The vertical dielectric patterns VIP may include, for example, one or more of oxide, nitride, and oxynitride.

Separation dielectric patterns 130 may be provided between neighboring first bit lines BL1 and between neighboring second bit lines BL2. The separation dielectric patterns 130 may extend in the first direction D1 and may be spaced apart from each other in the second direction D2 that is parallel to the top surface of the substrate 100 and intersects the first direction D1. The separation dielectric patterns 130 may include, for example, one or more of oxide, nitride, and oxynitride.

First and second word lines WL1a to WL1d and WL2a to WL2d may be provided between the first bit lines BL1 and the source lines SL. The first and second word lines WL1a to WL1d and WL2a to WL2d may extend in the third direction D3, while surrounding the first semiconductor patterns SP1 that are stacked in the third direction D3. For example, the first and second word lines WL1a to WL1d and WL2a to WL2d may have a gate-all-around (GAA) structure. The first and second word lines WL1a to WL1d and WL2a to WL2d may include portions interposed between the first semiconductor patterns SP1 that are vertically adjacent to each other.

As shown in FIG. 9B, each of the first and second word lines WL1a to WL1d and WL2a to WL2d may include a vertical part that runs across first and second lateral surfaces, which are opposite to each other in the first direction D1, of the first semiconductor patterns SP1 and may also include a horizontal part disposed between the first semiconductor patterns SP1 that are vertically adjacent to each other. Likewise, the second word lines WL2a to WL2d may include a vertical part and a horizontal part.

Third and fourth word lines WL3a to WL3d and WL4a to WL4d may be provided between the second bit lines BL2 and the source lines SL. The third and fourth word lines WL3a to WL3d and WL4a to WL4d may extend in the third direction D3, while surround the second semiconductor patterns SP2 that are stacked in the third direction D3. Likewise the first word lines WL1a to WL1d discussed above, each of the third and fourth word lines WL3a to WL3d and WL4a to WL4d may include a horizontal part interposed between the second semiconductor patterns SP2 that are vertically adjacent to each other.

As discussed above, ferroelectric patterns FEL may be correspondingly interposed between the intrinsic regions IR of the second semiconductor patterns SP2 and the third and fourth word lines WL3a to WL3d and WL4a to WL4d.

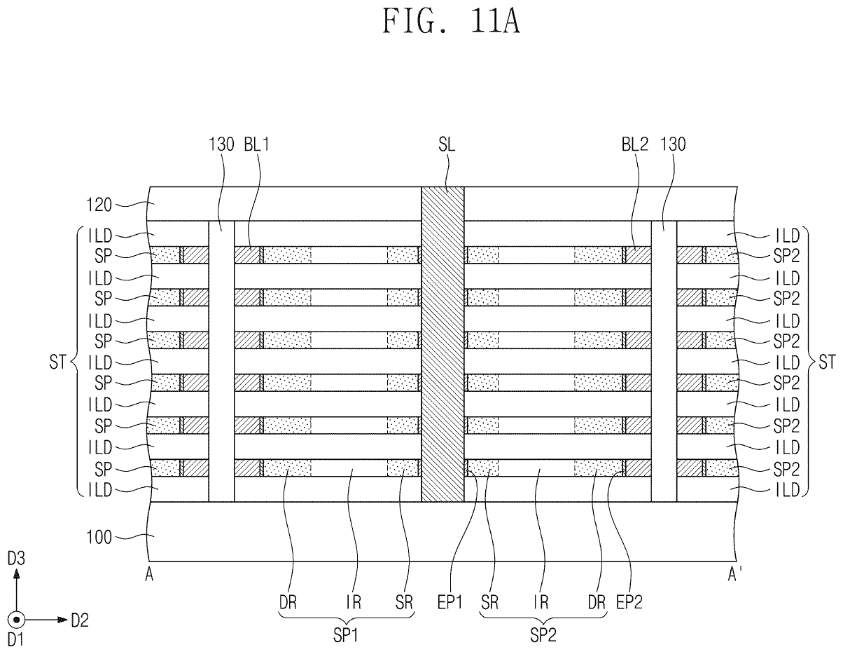

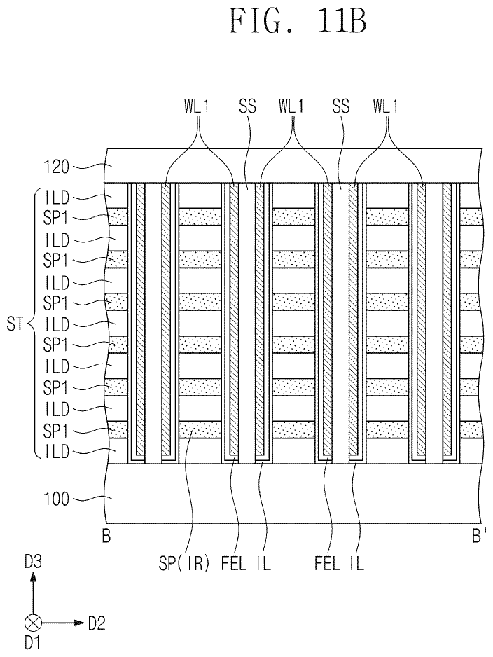

FIG. 10 illustrates a plan view showing a semiconductor memory device according to various example embodiments. FIG. 11A illustrates a cross-sectional view taken along line A-A′ of FIG. 10, showing a semiconductor memory device according to various example embodiments. FIG. 11B illustrates a cross-sectional view taken along line B-B′ of FIG. 10, showing a semiconductor memory device according to various example embodiments. For brevity of description, omission will be made in explaining technical features the same as those of the semiconductor memory device discussed above.

Referring to FIGS. 10, 11A, and 11B, a substrate 100 may be provided thereon with stack structures ST including interlayer dielectric layers ILD and ones of first and second semiconductor patterns SP1 and SP2. The stack structures ST may be disposed spaced apart from each other along a first direction D1 and a second direction D2 on the substrate 100.

In each stack structure ST, as discussed above, each of the first and second semiconductor patterns SP1 and SP2 may have a shape that has a major axis in the second direction D2. Each of the first and second semiconductor patterns SP1 and SP2 may include a source region SR, a drain region DR spaced apart in the second direction D2 from the source region SR, and an intrinsic region IR between the source and drain regions SR and DR. The source and drain regions SR and DR may have different semiconductor conductivity types from each other. In addition, each of the first and second semiconductor patterns SP1 and SP2 may have a first lateral surface and a second lateral surface that are opposite to each other in the first direction D1.

As described, first and second word lines WL1 and WL2 may run across the first and second lateral surface of the first semiconductor patterns SP1. For example, the first semiconductor patterns SP1 that are vertically stacked may be disposed between a pair of first word lines WL1 and between a pair of second word lines WL2. A ferroelectric pattern FEL may be disposed between the first and second word lines WL1 and WL2 and the first and second lateral surfaces of the first semiconductor patterns SP1, and a gate dielectric pattern IL may be disposed between the ferroelectric pattern FEL and the first and second lateral surfaces of the first semiconductor patterns SP1. The ferroelectric pattern FEL and the gate dielectric pattern IL may extend in a third direction D3 perpendicular to a top surface of the substrate 100.

Vertical spacers SS may be disposed between the first word lines WL1 that face each other in the first direction D1 and between the second word lines WL2 that face each other in the first direction D1.

Third and fourth word lines WL3 and WL4 may run across the first and second lateral surfaces of the second semiconductor patterns SP2. For example, the second semiconductor patterns SP2 that are vertically stacked may be disposed between a pair of third word lines WL3 and between a pair of fourth word lines WL4. Vertical spacers SS may be disposed between the third word lines WL3 that face each other in the first direction D1 and between the fourth word lines WL4 that face each other in the first direction D1.

A ferroelectric pattern FEL may be disposed between the third and fourth word lines WL3 and WL4 and the first and second lateral surfaces of the second semiconductor patterns SP2, and a gate dielectric pattern IL may be disposed between the ferroelectric pattern FEL and the first and second lateral surfaces of the second semiconductor patterns SP2.

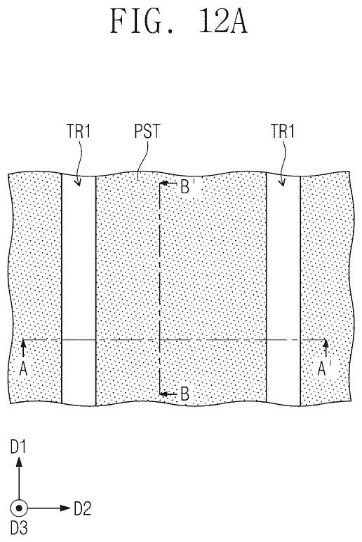

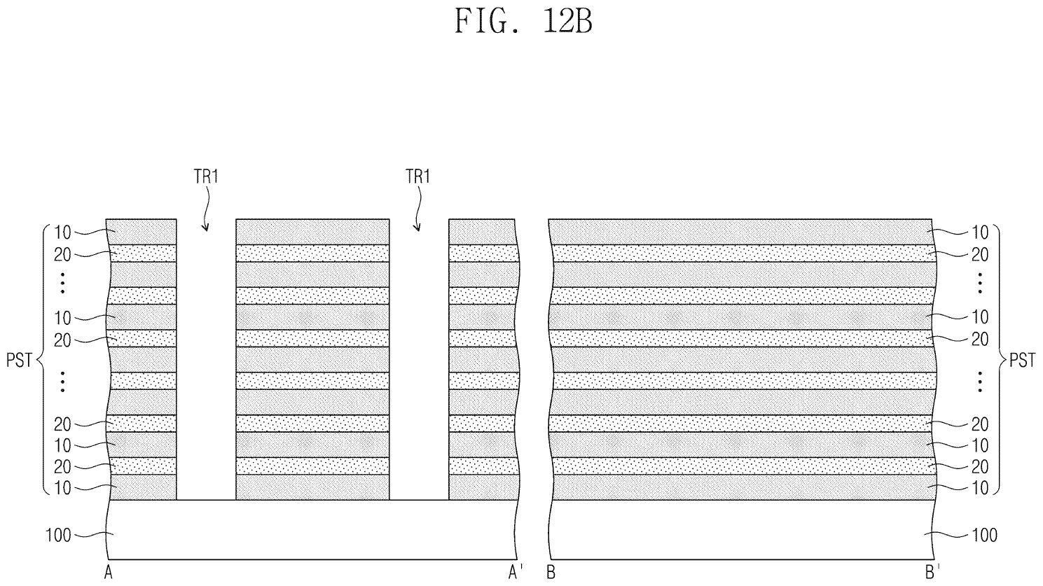

FIGS. 12A, 13A, 14A, 15A, 16A, 17A, 18A, and 19A illustrate plan views showing a method of fabricating a semiconductor memory device according to some example embodiments. FIGS. 12B, 13B, 14B, 15B, 16B, 17B, 18B, and 19B illustrate cross-sectional views taken along lines A-A′ and B-B′ of FIGS. 12A, 13A, 14A, 15A, 16A, 17A, 18A, and 19A, showing a method of fabricating a semiconductor memory device according to some example embodiments.

Referring to FIGS. 12A and 12B, sacrificial layers 10 and semiconductor layers 20 may be alternately stacked on a substrate 100 such that a preliminary stack structure PST may be formed on the substrate 100.

The sacrificial layers 10 may be formed of a material having an etch selectivity with respect to semiconductor layers 20. The sacrificial layers 10 may be formed of, for example, at least one selected from silicon germanium, silicon oxide, silicon nitride, and silicon oxynitride. In some example embodiments, the sacrificial layers 10 may be silicon-germanium layers. When the preliminary stack structure PST is formed, each sacrificial layer 10 may have a thickness less than that of each semiconductor layer 20.

In some example embodiments, the sacrificial layers 10 and the semiconductor layers 20 may be formed with an atomic layer deposition (ALD) process; however, example embodiments are not limited thereto. In some example embodiments, a thickness of each of the sacrificial layers 10 may be the same as each other, or at least one thickness may be different from (greater than or less than) at least another. In some example embodiments, a thickness of each of the semiconductor layers 20 may be the same as each other, or at least one thickness may be different from (greater than or less than) at least another.

The semiconductor layers 20 may include, for example, one or more of silicon, germanium, silicon-germanium, or indium gallium zinc oxide (IGZO). In some example embodiments, the semiconductor layers 20 may include a semiconductor material the same as that of the substrate 100. For example, the semiconductor layers 20 may be a monocrystalline silicon layer or a polycrystalline silicon layer.

The preliminary stack structure PST may be patterned to form first trenches TR1 through which the substrate 100 is exposed. The first trenches TR1 may have line shapes that extend along a first direction D1, and may be arranged spaced apart from each other along a second direction D2.

The formation of the first trenches TR1 may include forming on the preliminary stack structure PST a mask pattern such as a hardmask pattern (not shown) having openings that correspond to the first trenches TR1, and using the mask pattern as an etching mask to anisotropically etch the preliminary stack structure PST.

The first trenches TR1 may expose a top surface of the substrate 100, and during the anisotropic etching process, the preliminary stack structure PST may be over-etched to recess the top surface of the substrate 100 below the first trenches TR1.

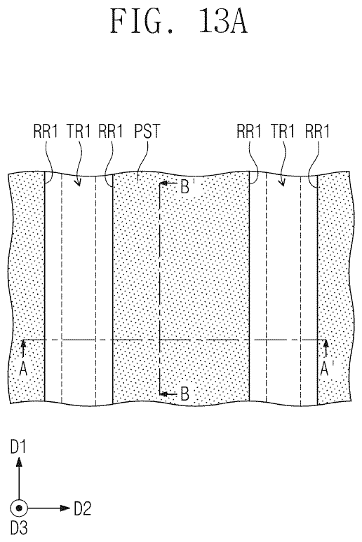

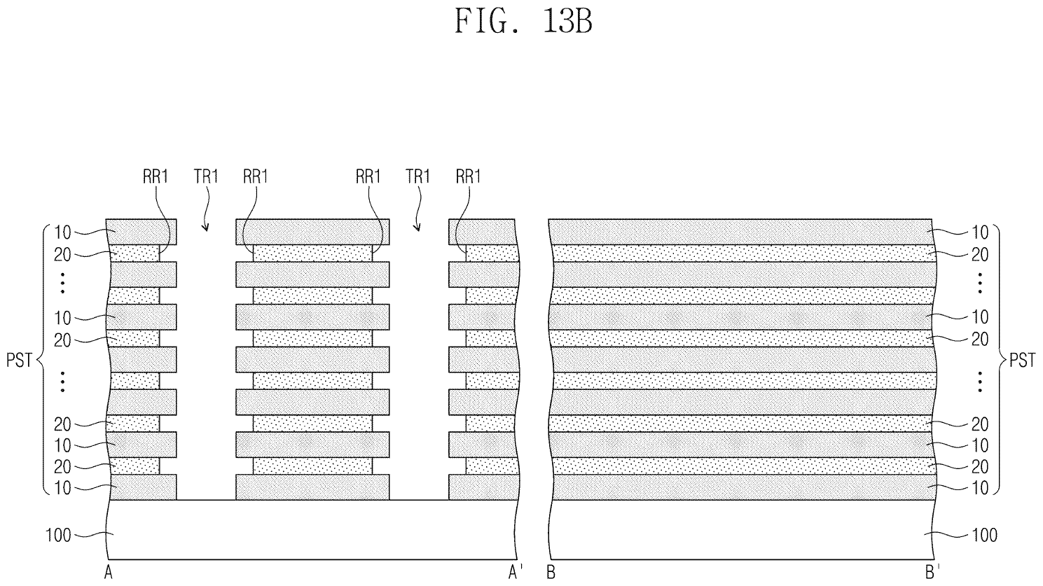

Referring to FIGS. 13A and 13B, the semiconductor layers 20 may be selectively etched at their portions exposed to the first trenches TR1 to thereby form first recess regions RR1 between the sacrificial layers 10.

The formation of the first recess regions RR1 may include etching portions of the semiconductor layers 20 by performing an etching process that has an etch selectivity with respect to the substrate 100 and the sacrificial layers 10. In some example embodiments, the etching of the semiconductor layers may include a wet etch; however, example embodiments are not limited thereto.

Each of the first recess regions RR1 may be formed between the sacrificial layers 10 that are vertically adjacent to each other. The first recess regions RR1 may extend in the first direction D1.

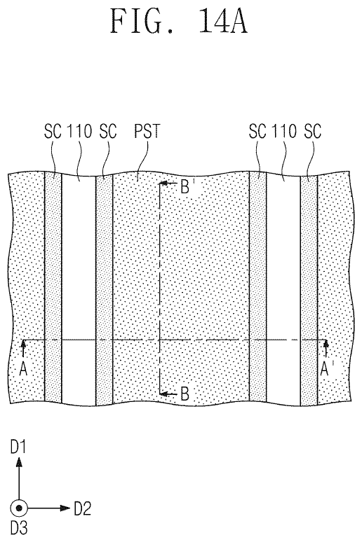

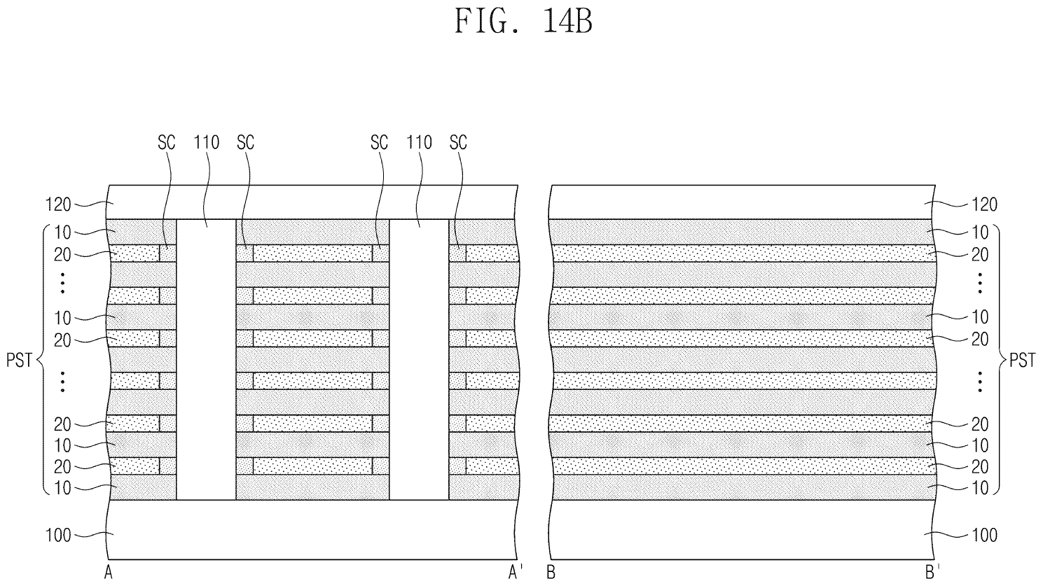

Referring to FIGS. 14A and 14B, sacrificial lines SC may be formed to fill the first recess regions RR1.

The formation of the sacrificial lines SC may include depositing (e.g., conformally depositing) a dielectric layer that fills the first recess regions RR1 and portions of the first trenches TR1, and then removing a dielectric material from the first trenches TR1 to locally leave the dielectric material in the first recess regions RR1.

After the formation of the sacrificial lines SC, first buried dielectric patterns 110 may be formed to fill the first trenches TR1. The first buried dielectric patterns 110 may separate the sacrificial lines SC from each other in the second direction D2.

The formation of the first buried dielectric patterns 110 may include forming a buried dielectric layer in the first trenches TR1, and then etching the buried dielectric layer to expose a top surface of an uppermost sacrificial layer 10. The first buried dielectric patterns 110 may be formed of one of or more than one of a silicon oxide layer, a silicon nitride layer, and a silicon oxynitride layer, and the buried dielectric layer may be etched by using a planarization technique such as a chemical mechanical polishing process and/or an etch-back process.

An upper dielectric layer 120 may be formed on the preliminary stack structure PST, covering the uppermost sacrificial layer 10. The upper dielectric layer 120 may be formed of a dielectric material that has an etch selectivity with respect to the sacrificial layers 10 and the semiconductor layers 20.

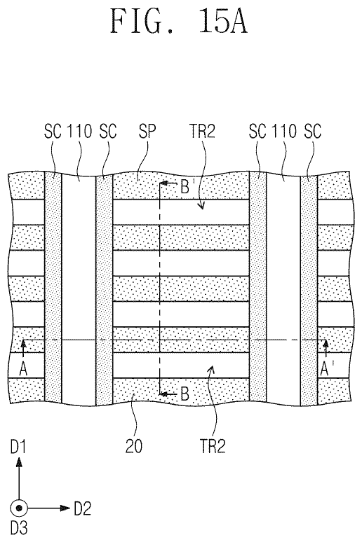

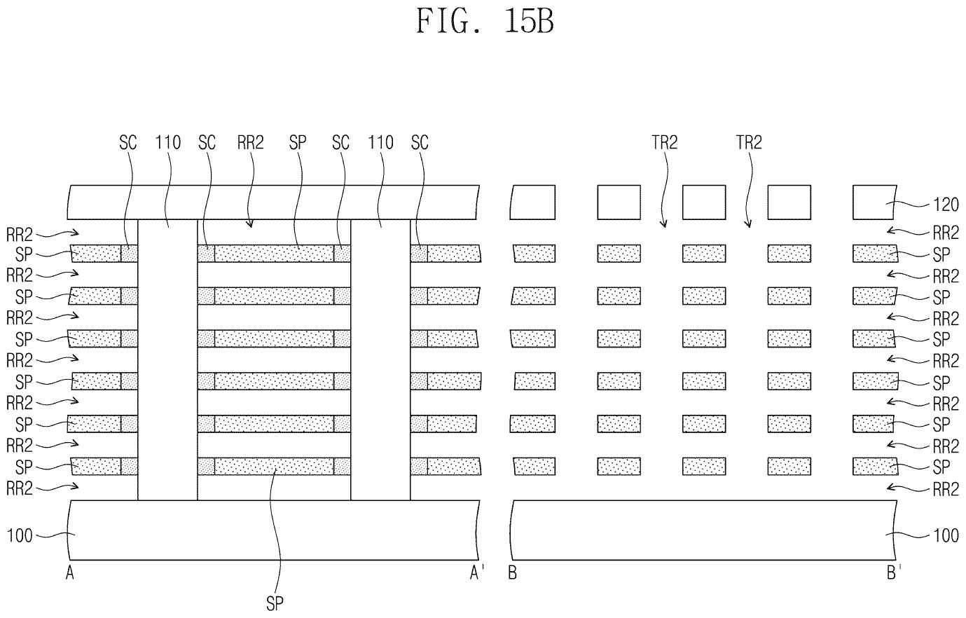

Referring to FIGS. 15A and 15B, the upper dielectric layer 120 and the preliminary stack structure PST may be patterned to form second trenches TR2 through which the substrate 100 is exposed.

The second trenches TR2 may have their bar shapes that parallel extend in the second direction D2, and may be spaced apart from each other in the first direction D1 and the second direction D2.

The formation of the second trenches TR2 may include forming on the preliminary stack structure PST a mask pattern such as a hardmask pattern (not shown) having openings that correspond to the second trenches TR2, and using the mask pattern as an etching mask to anisotropically etch the preliminary stack structure PST. The second trenches TR2 may expose the top surface of the substrate 100 and sidewalls of the sacrificial layer 10 and the semiconductor layer 20, and during the anisotropic etching process, the preliminary stack structure PST may be over-etched to recess the top surface of the substrate 100 below the second trenches TR2.

The formation of the second trenches TR2 may convert the semiconductor layers 20 into semiconductor patterns SP each shaped like a bar that has a major axis in the second direction D2. For example, the semiconductor patterns SP may be separated from each other in the first direction D1.

The sacrificial layers 10 exposed to the second trenches TR2 may be etched to form second recess regions RR2 between the semiconductor patterns SP that are vertically adjacent to each other.

The formation of the second recess regions RR2 may include performing an etching process that has an etch selectivity with respect to the substrate 100, the semiconductor patterns SP, and the upper dielectric layer 120. When the sacrificial layers 10 are removed, the first buried dielectric patterns 110 and the sacrificial lines SC may cause the semiconductor patterns SP to be vertically spaced apart from each other without collapsing.

A vertical thickness of the second recess region RR2, or a vertical distance between neighboring semiconductor patterns SP, may be substantially the same as the thickness of the sacrificial layer 10.

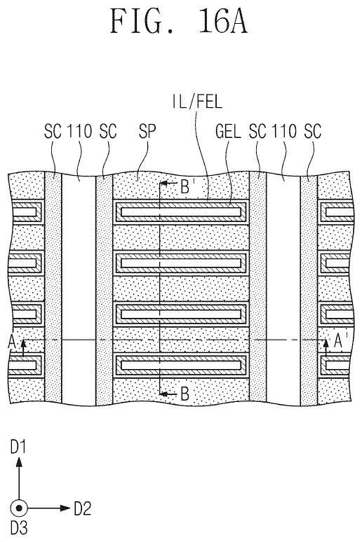

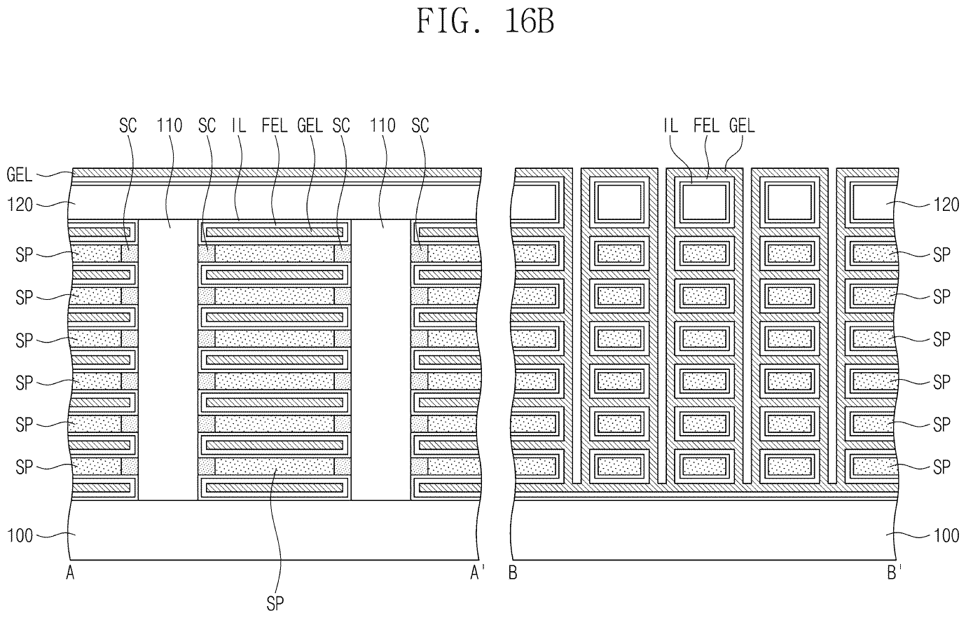

Referring to FIGS. 16A and 16B, a gate dielectric layer IL, a ferroelectric layer FEL, and a gate conductive layer GEL may be sequentially deposited in the second recess regions RR2 and the second trenches TR2. An atomic layer deposition (ALD) process or a chemical vapor deposition (CVD) process may be used to form the gate dielectric layer IL, the ferroelectric layer FEL, and the gate conductive layer GEL.

Each of the second recess regions RR2 may be filled with the gate dielectric layer IL, the ferroelectric layer FEL, and the gate conductive layer GEL, and the second trenches TR2 may not be completely filled with the gate dielectric layer IL, the ferroelectric layer FEL, and the gate conductive layer GEL.

The gate dielectric layer IL may include a high-k dielectric layer, a silicon oxide layer, a silicon nitride layer, a silicon oxynitride layer, or a combination thereof. The ferroelectric layer FEL may be formed of a dielectric material including hafnium. The ferroelectric layer FEL may include, for example, at least one of HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂. The gate conductive layer GEL may include one or more of a metal layer and a metal nitride layer.

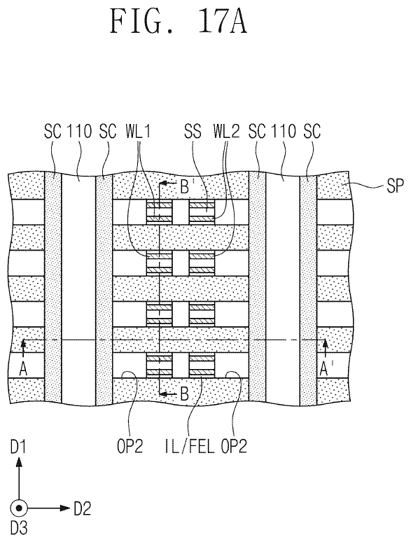

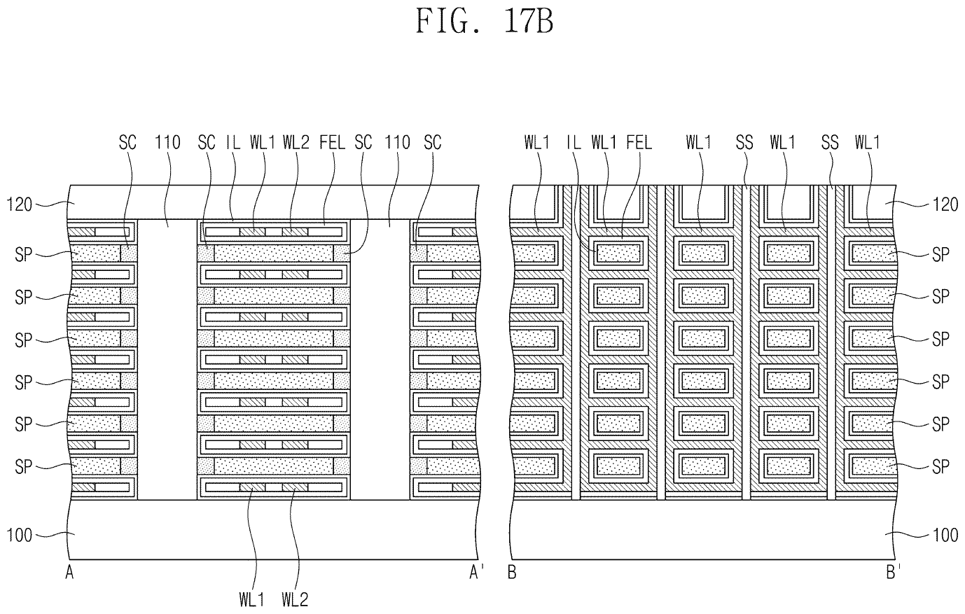

Referring to FIGS. 17A and 17B, an anisotropic etching process or an etch-back process may be performed on the gate dielectric layer IL, the ferroelectric layer FEL, and the gate conductive layer GEL. Therefore, the top surface of the substrate 100 may be exposed on bottoms of the second trenches TR2.

A spacer dielectric layer SS may fill the second trenches TR2 in which are formed the gate dielectric layer IL, the ferroelectric layer FEL, and the gate conductive layer GEL. The sacrificial dielectric layer SS may be one of dielectric materials and silicon oxides that are formed by using spin-on-glass (SOG) technology.

A patterning process may be performed on the gate dielectric layer IL, the ferroelectric layer FEL, and the gate conductive layer GEL that fill each of the second trenches TR2, and therefore vertical openings OP2 may be formed to expose the substrate 100. Accordingly, each of the second trenches TR2 may be provided therein with first and second word lines WL1 and WL2 that are formed separated from each other in the second direction D2. The patterned gate dielectric layer IL and the patterned ferroelectric layer FEL may be called a gate dielectric pattern IL and a ferroelectric pattern FEL, respectively.

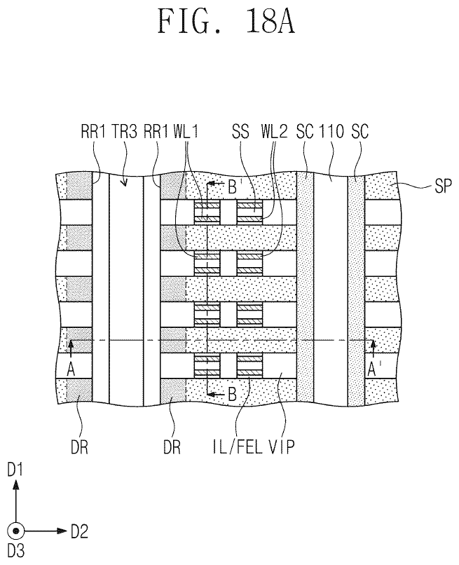

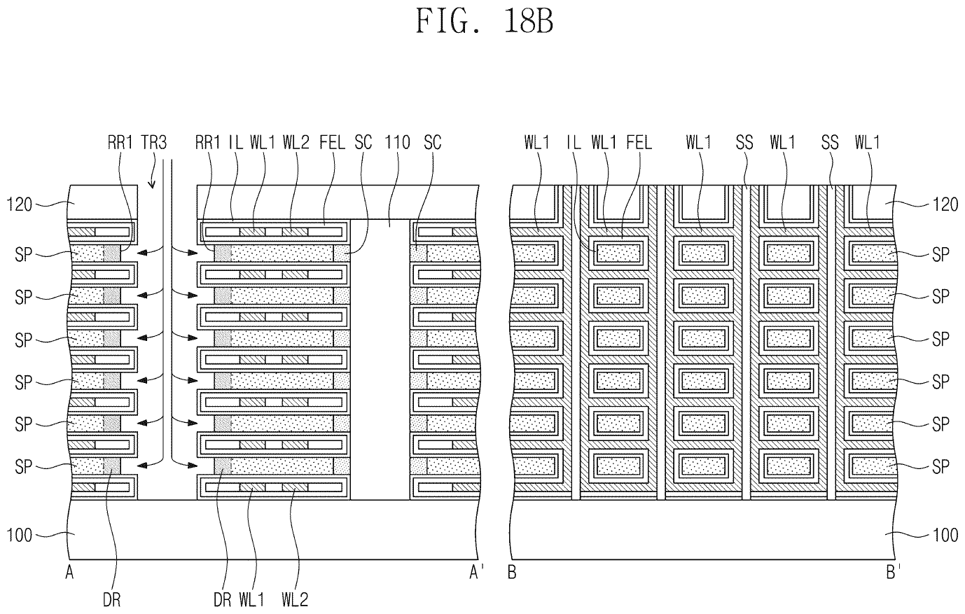

Referring to FIGS. 18A and 18B, after the formation of the first and second word lines WL1 and WL2, the vertical openings OP2 may be filled with vertical dielectric patterns VIP. In each second trench TR2, the vertical dielectric patterns VIP may be formed between the sacrificial line SC and the first word line WL1, between the first word line WL1 and the second word line WL2, and between the second word line WL2 and the sacrificial line SC.

The vertical dielectric pattern VIP may extend in a third direction D3 on the substrate 100, and may separate the semiconductor patterns SP that are adjacent to each other in the first direction D1. The vertical dielectric pattern VIP may be one of dielectric materials and silicon oxides that are formed by using spin-on-glass (SOG) technology.

A mask pattern such as a hardmask pattern (not shown) having a linear opening may be formed on the upper dielectric layer 120. The mask pattern may be used as an etching mask to etch the upper dielectric layer 120 and one of the first buried dielectric patterns 110, and thus a third trench TR3 may be formed to expose the substrate 100. The third trench TR3 may expose the sacrificial lines SC and sidewalls of the gate dielectric pattern IL.

The sacrificial lines SC exposed to the third trench TR3 may be selectively removed to form again the first recess regions RR1 that expose first sidewalls of the semiconductor patterns SP.

After the formation again of the first recess regions RR1, an impurity doping region may be performed to form drain regions DR on the first sidewalls of the semiconductor patterns SP.

One or more of gas phase doping (GPD), beam-line ion implantation, and plasma assisted doping (PLAD) may be performed as the impurity doping process; example embodiments are not limited thereto. After the impurity doping process, an annealing process may be performed.

In the impurity doping process, a gas including impurities having a first conductivity type (e.g., n-type) may be uniformly provided in the third trench TR3, and the impurities may be doped into the first sidewalls of the semiconductor layers 20 exposed to the first recess regions RR1. In the drain region DR, a concentration of the impurities having the first conductivity type may gradually decrease with decreasing distance from the first sidewall of the semiconductor pattern SP.

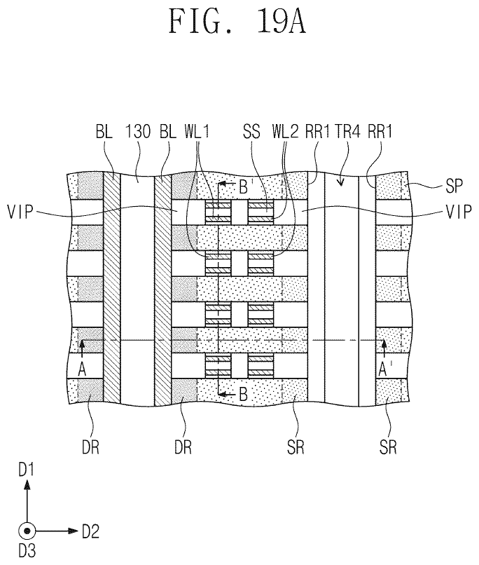

Referring to FIGS. 19A and 19B, after the formation of the drain regions DR, bit lines BL may be formed in the first recess regions RR1.

The formation of the bit lines BL may include depositing a conductive layer that fills the first recess regions RR1 and a portion of the third trench TR3, and then etching the conductive layer in the third trench TR3 to locally leave the conductive layer in the first recess regions RR1. When the conductive layer is etched, the gate dielectric pattern IL or the ferroelectric pattern FEL may be used as an etch stop layer. In addition, while the conductive layer is etched, the gate dielectric pattern IL or the ferroelectric pattern FEL may be partially etched. In some example embodiments, each bit line BL may extend in the first direction D1, and may be in contact with the first sidewalls of the semiconductor patterns SP arranged along the first direction D1 and sidewalls of the vertical dielectric patterns VIP arranged along the first direction D1. In addition, top and bottom surfaces of each bit line BL may be in contact with the gate dielectric pattern IL.

After the formation of the bit lines BL, a separation dielectric pattern 130 may be formed in the third trench TR3. The separation dielectric pattern 130 may be one of dielectric materials and silicon oxides that are formed by using spin-on-glass (SOG) technology.

A mask pattern such as a hardmask pattern (not shown) having a linear opening may be formed on the upper dielectric layer 120. The mask pattern may be used as an etching mask to etch the upper dielectric layer 120 and another of the first buried dielectric patterns 110, and thus a fourth trench TR4 may be formed to expose the substrate 100. The fourth trench TR4 may expose the sacrificial line SC and sidewalls of the gate dielectric pattern IL.

The sacrificial lines SC exposed to the fourth trench TR4 may be selectively removed to form again the first recess regions RR1 that expose second sidewalls of the semiconductor patterns SP.

After the formation again of the first recess regions RR1, an impurity doping process may be performed to form source regions SR on the second sidewalls of the semiconductor patterns SP. The source regions SR may be formed by using the impurity doping process as discussed above. In the impurity doping process to form the source regions SR, a gas including impurities having a second conductivity type (e.g., n-type) may be uniformly provided in the fourth trench TR4.

After the formation of the source regions SR, source lines SL may be formed in the first recess regions RR1 and the fourth trench TR4.

The formation of the source lines SL may include depositing a conductive layer that completely fills the first recess regions RR1 and the fourth trench TR4, and patterning the conductive layer to separate the conductive layer in the first direction D1.

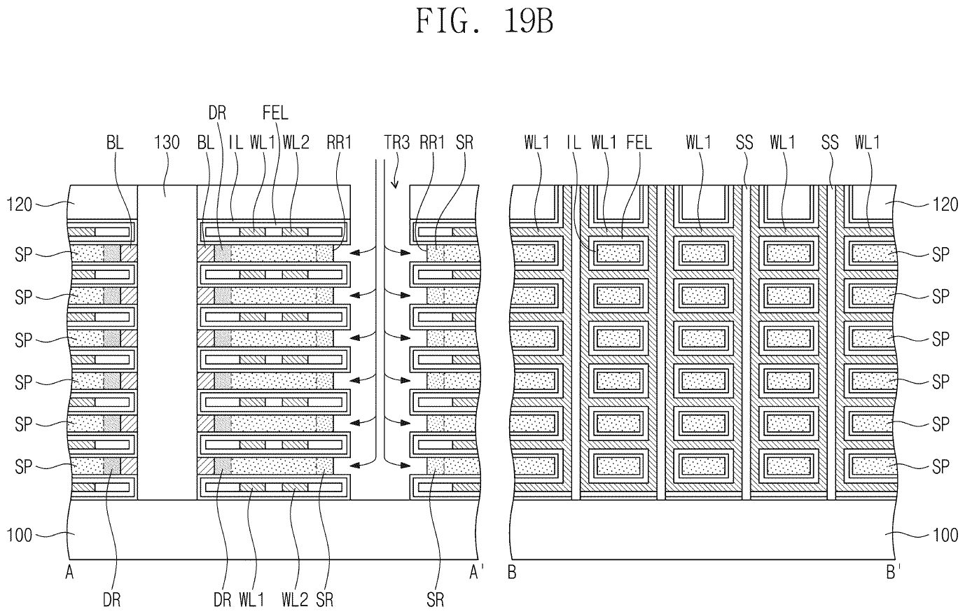

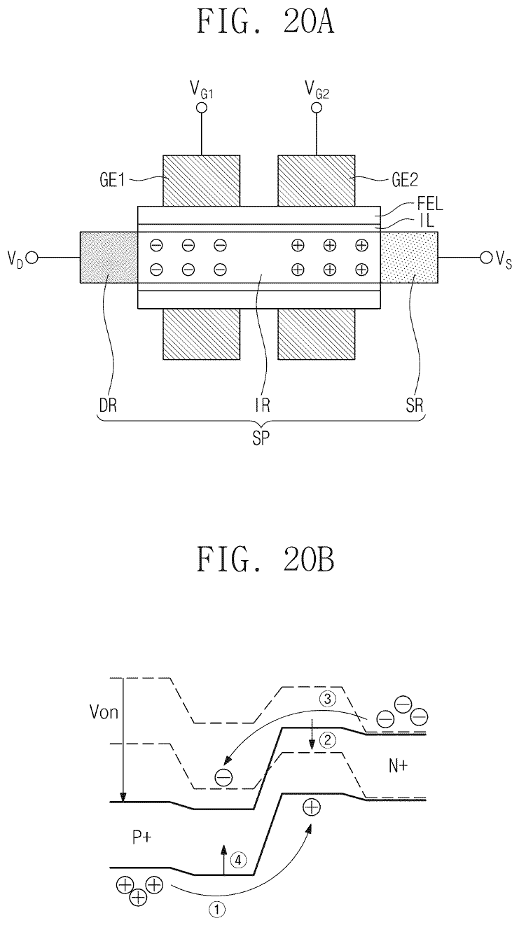

FIGS. 20A and 20B illustrate diagrams showing an operation in a volatile memory mode of a semiconductor memory device according to some example embodiments.

Referring to FIGS. 20A and 20B, a first gate voltage V_{G1} and a second gate voltage V_{G2} may be respectively applied to the first gate electrode GE1 and the second gate electrode GE2. In an operation of a volatile memory mode, for example, the first gate voltage V_{G1} and the second gate voltage V_{G2} may be about −3 V and 3 V, respectively.

In an operation of a volatile memory mode, the complementary first and second gate voltages V_{G1} and V_{G2} are applied, a potential barrier may be formed in the intrinsic region IR of the semiconductor pattern SP. When the first gate voltage V_{G1} is greater than the second gate voltage V_{G2}, the first gate voltage V_{G1} may change an energy level of the intrinsic region IR as if doped with impurities having a first conductivity type, and the second gate voltage V_{G2} may change an energy level of the intrinsic region IR as if doped with impurities having a second conductivity type. Therefore, an energy barrier may be formed in the intrinsic region IR having an intrinsic state. For example, a p-i-n structure of the semiconductor pattern SP may be changed into a p-n-p-n structure. The source voltage Vs may be a ground voltage.

For example, electrons may be stored in the semiconductor pattern SP adjacent to the first gate electrode GE1, and holes may be stored in the semiconductor pattern SP adjacent to the second gate electrode GE2. As such, in a state with an energy level of the p-n-p-n structure, when the drain voltage VD (e.g., about 1 V) is applied to a bit line connected to the drain region DR, an energy barrier between the drain region DR and the intrinsic region IR may increase such that almost no drain current may flow through the semiconductor pattern SP. Thus, data “0” may be written to a unit cell. In this case, almost no current may flow through the unit cell, and this may be sensed as data “0”.

Afterwards, when the drain voltage VD (e.g., about 1 V) is applied to a bit line connected to the drain region DR, the energy barrier between the drain region DR and the intrinsic region IR may decrease as indicated by \textcircled{4}, and holes of the drain region DR may move to the intrinsic region IR as indicated by \textcircled{1}.

The hole that has moved to the intrinsic region IR may decrease an energy barrier between an n-type impurity region (N+) and the intrinsic region IR, as indicated by \textcircled{2}.

When there is a reduction in energy barrier between the source region SR and the intrinsic region IR, electrons of the source region SR may move to the intrinsic region IR, as indicated by \textcircled{3}.

The electron that has moved to the intrinsic region IR may additionally decrease an energy barrier between the drain region DR and the intrinsic region IR. Thus, a positive feedback loop may be created to collapse an energy barrier of a channel, and thus data “1” may be written to the unit cell. For example, an energy barrier between the source and drain regions SR and DR may be abruptly annihilated and simultaneously the semiconductor pattern SP may act as a diode in a forward bias state as shown in FIG. 20B. In this case, a current may flow through the unit cell, and this may be sensed as data “1”.

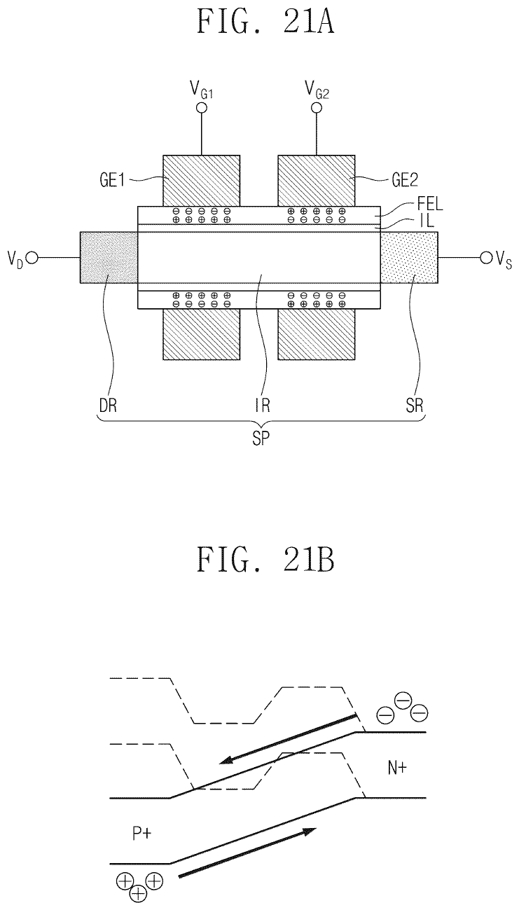

FIGS. 21A and 21B illustrate diagrams showing an operation in a non-volatile memory mode of a semiconductor memory device according to some example embodiments.

Referring to FIGS. 21A and 21B, in an operation of a non-volatile memory mode, the first and second gate voltages V_{G1} and V_{G2} may be greater in the non-volatile memory mode than in the volatile memory mode. In an operation of a non-volatile memory mode, for example, the first gate voltage V_{G1} and the second gate voltage V_{G2} may be about −11 V and 11V, respectively. The complimentary first and second gate voltages V_{G1} and V_{G2} may be applied to change an energy level of the intrinsic region IR adjacent to the first gate electrode GE1 and an energy level of the intrinsic region IR adjacent to the second gate electrode GE2. A polarization direction of the ferroelectric pattern FEL may be changed due to a difference in voltage between the intrinsic region IR and one of the first and second gate voltages V_{G1} and V_{G2} applied to the first and second gate electrodes GE1 and GE2. The difference in voltage between the intrinsic region IR and one of the first and second gate voltages V_{G1} and V_{G2} may be equal to or greater than a minimum voltage required for changing polarization of the ferroelectric pattern FEL.

A polarization state of the ferroelectric pattern FEL may be determined by a difference in voltage between the intrinsic region IR and the first and second gate electrodes GE1 and GE2. As the complementary first and second gate voltages V_{G1} and V_{G2} are applied, the ferroelectric pattern FEL adjacent to the first gate electrode GE1 may have a positive polarization state, and the ferroelectric pattern FEL adjacent to the second gate electrode GE2 may have a negative polarization state.

The first gate voltage V_{G1} or the second gate voltage V_{G2} may create polarization, and the polarization may be maintained even when an external electric field is absent. As the ferroelectric pattern FEL maintains its polarization, even though no voltage is applied to the source and drain regions SR and DR, an electric field due to polarization may cause the intrinsic region IR to have charges, with the result that data may be maintained.

An energy barrier between the source and drain regions SR and DR may be reduced to allow the semiconductor pattern SP to act as a diode in a forward bias state as shown in FIG. 21B.

According to some example embodiments, memory cells devoid of separate data storage elements may be three-dimensionally achieved on a substrate. Alternatively or additionally, a semiconductor memory device may operate as a volatile or non-volatile memory device according to voltages applied to first and second gate electrodes.

As the semiconductor memory device includes a single-layered ferroelectric pattern as a data storage element for each memory cell, it may be advantageous to increase integration of the semiconductor memory device.

Alternatively or additionally, when the semiconductor memory device operates as a volatile memory device, the speed of switching of polarization state in the ferroelectric pattern may be so fast that there may be a reduction in standby current for data maintenance. Accordingly, the semiconductor memory device may decrease in standby current.

Although various example embodiments have been described in connection with some example embodiments illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device, comprising:
a substrate;
a semiconductor pattern on the substrate, wherein the semiconductor pattern includes,
a source region having a first conductivity type,
a drain region having a second conductivity type, and
an intrinsic region between the source region and the drain region;
first and second gate electrodes on the intrinsic region;
a ferroelectric pattern between the intrinsic region and the first and second gate electrodes; and
a gate dielectric pattern between the ferroelectric pattern and the intrinsic region.

2. The semiconductor memory device of claim 1, further comprising:
a dielectric pillar on the substrate,
wherein the semiconductor pattern surrounds a sidewall of the dielectric pillar.

3. The semiconductor memory device of claim 1, wherein the source region and the drain region are spaced apart from each other in a first direction parallel to a top surface of the substrate.

4. The semiconductor memory device of claim 3, further comprising:
a bit line that extends along a second direction parallel to the top surface of the substrate, the second direction intersecting the first direction,
wherein the bit line is connected to one of the source region or the drain region of the semiconductor pattern.

5. The semiconductor memory device of claim 4, further comprising:
a source line that extends along a third direction different from the first direction and the second direction,
wherein the source line is connected to another of the source region or the drain region of the semiconductor pattern.

6. The semiconductor memory device of claim 1, wherein a length of the drain region is different from a length of the source region.

7. The semiconductor memory device of claim 1, wherein each of the first and second gate electrodes surrounds the semiconductor pattern and is perpendicular to a top surface of the substrate.

8. The semiconductor memory device of claim 1, wherein the ferroelectric pattern surrounds the semiconductor pattern.

9. The semiconductor memory device of claim 1, wherein the ferroelectric pattern includes at least one of HfO₂, HfSiO₂, HfAlO₂, HfSiON, HfZnO, HfZrO₂, ZrO₂, ZrSiO₂, HfZrSiO₂, ZrSiON, LaAlO, HfDyO₂, or HfScO₂.

10. A semiconductor memory device, comprising:
a substrate;
a plurality of semiconductor patterns that are stacked along a first direction perpendicular to a top surface of the substrate, wherein each of the plurality of semiconductor patterns includes:
a source region having a first conductivity type,
a drain region having a second conductivity type, and
an intrinsic region between the source region and the drain region;
first and second word lines that surround the intrinsic regions of the plurality of semiconductor patterns and extend in the first direction;
a plurality of ferroelectric patterns between respective ones of the semiconductor patterns and the first and second word lines, the plurality of ferroelectric patterns surrounding the intrinsic regions of the respective semiconductor patterns;
a plurality of gate dielectric patterns between respective ones of the plurality of ferroelectric patterns and the plurality of semiconductor patterns;
a plurality of bit lines that extend along a second direction parallel to the top surface of the substrate and are connected to one of the source regions or the drain regions of the plurality of semiconductor patterns; and
a plurality of source lines that extend along the first direction and are connected to another of the source regions or the drain regions of the semiconductor patterns.

11. The semiconductor memory device of claim 10, wherein the first and second word lines are spaced apart from each other in a third direction that is parallel to the top surface of the substrate and intersects the second direction.

12. The semiconductor memory device of claim 10, wherein
each of the plurality of semiconductor patterns has first and second lateral surfaces that are opposite to each other in the second direction, and
each of the first and second word lines includes a vertical part that runs across the first and second lateral surfaces of the plurality of semiconductor patterns and a horizontal part between the plurality of semiconductor patterns adjacent to each other in the first direction.

13. The semiconductor memory device of claim 10, wherein the plurality of ferroelectric patterns, the gate dielectric pattern, at least a portion of the first word line, and at least a portion of the second word line fill between the plurality of semiconductor patterns adjacent to each other in the first direction.

14. The semiconductor memory device of claim 10, wherein each of the plurality of ferroelectric patterns has a cylindrical shape having a major axis in the second direction.

15. A semiconductor memory device, comprising:
a substrate;
a plurality of first bit lines that are stacked on the substrate and extend in a first direction parallel to a top surface of the substrate;
a plurality of second bit lines that are stacked on the substrate and extend in the first direction;
a plurality of source lines between the first and second bit lines, the plurality of source lines extending in a second direction perpendicular to the top surface of the substrate;
a plurality of first memory cells at intersections between respective ones of the plurality of first bit lines and the plurality of source lines; and
a plurality of second memory cells at intersections between respective ones of the plurality of second bit lines and the plurality of source lines,
wherein each of the plurality of first and second memory cells includes,
a semiconductor pattern that has a major axis in a third direction parallel to the top surface of the substrate, wherein the semiconductor pattern includes a source region having a first conductivity type, a drain region having a second conductivity type, and an intrinsic region between the source region and the drain region.
first and second gate electrodes that surround the intrinsic region of the semiconductor pattern,
a ferroelectric pattern between the semiconductor pattern and the first and second gate electrodes, and
a gate dielectric pattern between the ferroelectric pattern and the semiconductor pattern.

16. The semiconductor memory device of claim 15, further comprising:
a plurality of first word lines and a plurality of second word lines, the plurality of first and second word lines extending in the second direction,
wherein the plurality of first word lines are spaced apart from each other in the first direction and correspond to the first gate electrodes of the first memory cells, and
wherein the plurality of second word lines are spaced apart from each other in the first direction and correspond to the second gate electrodes of the second memory cells.

17. The semiconductor memory device of claim 16, further comprising:
a plurality of vertical spacers between the plurality of first word lines adjacent to each other in the first direction and between the plurality of second word lines adjacent to each other in the first direction.

18. The semiconductor memory device of claim 16, wherein each of the plurality of first and second word lines includes:
a vertical part that extends in the second direction; and
a horizontal part between the semiconductor patterns adjacent to each other in the second direction.

19. The semiconductor memory device of claim 15, wherein
the plurality of first bit lines are connected to one of the source regions or the drain regions of the semiconductor patterns included in the first memory cells, and
the plurality of second bit lines are connected to another of the source regions or the drain regions of the semiconductor patterns included in the second memory cells.

20. The semiconductor memory device of claim 15, wherein the plurality of source lines are connected to the source regions of the semiconductor patterns included in the first memory cells and the source regions of the semiconductor patterns included in the second memory cells.
